(19) United States
(12) Patent Application Publication
(10) Pub. No.: US 2026/0073098 A1
(43) Pub. Date: Mar. 12, 2026

(54) AUTOMATIC WELL INTERVENTION PLAN GENERATOR

(71) Applicant: Schlumberger Technology Corporation, Sugar Land, TX (US)

(72) Inventors: Omair Altaf, Beijing (CN); Daniel Gemmell, Kuala Lumpur (MY); Yangge Hu, Beijing (CN); Dian Jing, Beijing (CN); Wei Li, Beijing (CN); Wenrui Li, Beijing (CN); Ying Lu, Beijing (CN); Jamie McGee, Beijing (CN); Lihui Meng, Beijing (CN); Binrui Mu, Beijing (CN); Jordi Juan Segura Dominguez, Beijing (CN); Dawei Xu, Beijing (CN); Wen Jun Zhao, Beijing (CN)

(21) Appl. No.: 19/319,916

(22) Filed: Sep. 5, 2025

(30) Foreign Application Priority Data
Sep. 6, 2024 (CN) 202411253701.6
Sep. 6, 2024 (CN) 202411253702.0

(51) Int. Cl. G06F 30/27; E21B 47/022; E21B 47/04; E21B 47/06

(52) U.S. Cl. CPC G06F 30/27; E21B 47/022; E21B 47/04; E21B 47/06

(57) ABSTRACT

Aspects of the disclosure provide for automated well intervention planning. An automated well intervention planning system includes one or more memories storing computer executable code. The system includes a user interface configured to receive inputs from a user, the input including at least one or more well intervention objectives and one or more well conditions. The system includes one or more processors configured to execute the computer executable code. The one or more processors are configured to search a database for one or more well intervention plans associated the one or more well intervention objectives and the one or more well conditions and generate a well intervention plan based on the one or more well intervention plans.

### CROSS-REFERENCE TO RELATED APPLICATION(S)

The present disclosure claims priority from CN Appl. No. 202411253701, filed on Sep. 6, 2024, and CN Appl. No. 202411253702, filed on Sep. 6, 2024, both herein incorporated by reference in their entirety.

### BACKGROUND

### Field of the Disclosure

The disclosure relates to well intervention and, more particularly, to an automatic well intervention plan generator and to operation chance of success for well intervention planning.

### Description of Related Art

In the field of oil and gas exploration, the efficient extraction of hydrocarbon resources is critical for maximizing production and minimizing costs. As geographic locations are increasingly developed for the extraction of hydrocarbons, the proportion of hydrocarbon production coming from mature also increases. Therefore, maximizing the productivity and efficiency of existing wells, in turn, becomes increasingly important.

Well intervention is one approach to increasing productivity. At some point in the life of all oil and gas wells, parts will require maintenance, repair or replacement. At these times, operators may turn to intervention specialists. Interventions fall into two general categories: light or heavy. During light interventions, technicians lower tools or sensors into a live well while pressure is contained at the surface. In heavy interventions, the rig crew may stop production at the formation before making major equipment changes.

Well service personnel typically perform light interventions using slickline, wireline, or coiled tubing. These systems allow operators to minimize the possibility of potential well blockages. Operators also order light interventions to change or adjust downhole equipment such as valves or pumps, or to gather downhole pressure, temperature, and flow data. Heavy interventions—also referred to as workovers—may require the rig crew to remove the wellhead and other pressure barriers from the well to allow full access to the wellbore. These operations may require a rig to remove and reinstall the wellhead and completion equipment. Heavy interventions may be used to replace parts such as tubing strings and pumps that cannot be retrieved through light interventions. Some heavy interventions are performed to plug and abandon an original producing zone to reconfigure the well to produce from a secondary zone; these operations are known as recompletions.

Software may be used in planning well interventions. For example, well intervention software may be used to aid in selection of the wells to perform intervention, to determine the intervention approach that will yield the best results, and/or to generate a detailed work plan for the well intervention. Use of such well intervention software may increase the likelihood of success of the well intervention and maximize the productivity of the well. The well intervention software may provide an interactive tool for intervention planning. The intervention plan may include an operation plan, an inflow simulation, an estimated duration, an estimated probability of success, a production amount before intervention, an estimated production amount after intervention, a net present value (NPV), a listing of equipment and personnel to carry out an intervention operation, and an indicative price. The operation plan may include a series operations using intervention technologies, including a main workflow and a contingent workflow. A user can make an operation plan using the well invention software. The operation plan may be a starting point for the inflow simulation and the indicative price. One example software is the Intervention Advisor (IA) provided by Schlumberger Limited, Houston, Texas.

With current well intervention software, the user manually builds the intervention plan using the interactive well intervention software. The manual planning also includes the user inputting one or more probabilities of success for the intervention plan. For example, based on user's own expertise and knowledge, the user may input a probability of success for each intervention technology and operation in the well intervention plan. Such manual planning may be time consuming, may require expertise of the user, and is subject to human error.

There exists a need for further improvements in well intervention planning.

### SUMMARY

The disclosure provides techniques for automated well intervention planning.

Some aspects provide an automated well intervention planning system. The automated well intervention planning system includes one or more memories storing computer executable code. The automated well intervention planning system includes an interface configured to receive inputs. The inputs include at least one or more well intervention objectives and one or more well conditions. The automated well intervention planning system includes one or more processors configured to execute the computer executable code to generate a well intervention plan based on the inputs.

Some aspects provide a method for automated well intervention planning. The method for automated well intervention planning includes receiving inputs. The inputs including at least one or more well intervention objectives and one or more well conditions. The method for automated well intervention planning includes generating a well intervention plan based on the inputs.

Some aspects provide a computer readable medium storing computer executable code for automated well intervention planning. The computer executable code includes code for receiving inputs, the inputs including at least one or more well intervention objectives and one or more well conditions. The computer executable code includes code for generating a well intervention plan based on the inputs.

Some aspects provide an automated well intervention planning system. The automated well intervention planning system may include one or more memories storing computer executable code. The automated well intervention planning system may include a user interface or a data connection configured to receive inputs, the inputs including at least one or more well intervention operations and one or more well conditions. The automated well intervention planning system may include one or more processors configured to execute the computer executable code and: input the one or more well intervention operations and one or more well conditions to a predictive model; predict, using the predictive model, a well intervention operation probability of success for the one or more well intervention operations based, at least in part, on the one or more well conditions; and output the predicted well intervention operation probability of success for the one or more well intervention operations.

Some aspects provide a method for well intervention planning. The method for well intervention planning may include receiving inputs from a user or a data connection, the inputs including at least one or more well intervention operations and one or more well conditions; inputting the one or more well intervention operations and one or more well conditions to a predictive model; predicting, using the predictive model, a well intervention operation probability of success for the one or more well intervention operations based, at least in part, on the one or more well conditions; and outputting the predicted well intervention operation probability of success for the one or more well intervention operations.

Some aspects provide a computer readable medium storing computer executable code for well intervention planning. The computer executable code may include code for receiving inputs from a user or a data connection, the inputs including at least one or more well intervention operations and one or more well conditions; code for inputting the one or more well intervention operations and one or more well conditions to a predictive model; code for predicting, using the predictive model, a well intervention operation probability of success for the one or more well intervention operations based, at least in part, on the one or more well conditions; and code for outputting the predicted well intervention operation probability of success for the one or more well intervention operations.

The following description and the appended figures set forth certain features for purposes of illustration.

### BRIEF DESCRIPTION OF DRAWINGS

The figures show several embodiments of the system according to the disclosure.

FIG. 1 illustrates an example automatic well intervention plan generator system.

FIG. 2 depicts an example home display of a user interface of the automatic well intervention plan generator system.

FIG. 3 depicts an example well selection display of the user interface of the automatic well intervention plan generator system.

FIG. 4 depicts an example well intervention display of the user interface of the automatic well intervention plan generator system.

FIG. 5 depicts an example plan overview display for market and/or environment selection of the user interface of the automatic well intervention plan generator system.

FIG. 6 depicts another example plan overview display for well symptom selection of the user interface of the automatic well intervention plan generator system.

FIG. 7 depicts another example plan overview display for intervention type selection of the user interface of the automatic well intervention plan generator system.

FIG. 8 depicts an example pre-intervention display of the user interface of the automatic well intervention plan generator system.

FIG. 9 depicts an example pre-intervention display for completion information of the user interface of the automatic well intervention plan generator system.

FIG. 10 depicts an example pre-intervention display for trajectory information of the user interface of the automatic well intervention plan generator system.

FIG. 11 depicts an example pre-intervention display for operational data information of the user interface of the automatic well intervention plan generator system.

FIG. 12 depicts an example intervention display of the user interface of the automatic well intervention plan generator system.

FIG. 13 depicts an example intervention display for an automatically generated well intervention plan report of the user interface of the automatic well intervention plan generator system.

FIG. 14A depicts example collected historical well intervention plan information.

FIG. 14B depicts example statistical associations of the collected historical well intervention plan information of FIG. 14A.

FIG. 15 is a flow diagram depicting an example method for automatic well intervention plan generation.

FIG. 16 is an example processing system for automatic well intervention plan generation.

FIG. 17 illustrates an example well intervention planning system.

FIG. 18A depicts an example intervention display for a decision tree of the user interface of the well intervention planning system.

FIG. 18B depicts another example intervention display for the decision tree of the user interface of the well intervention planning system.

FIG. 19 depicts an example machine learning algorithm for predictive intervention operation chance of success.

FIG. 20 is a flow diagram depicting an example method for predictive intervention operation chance of success for the well intervention planning.

FIG. 21 is an example processing system for predictive intervention operation chance of success for the well intervention planning.

### DETAILED DESCRIPTION

The disclosure provides techniques, methods, systems, apparatus, and computer readable media for automated intervention planning and predictive intervention operation probability of success for well intervention planning.

According to certain aspects, a well intervention may involve various intervention operations associated with various intervention technologies. In some aspects, the various intervention operations and technologies may be performed according to a specified sequence. The sequence of well intervention technologies and operations may be referred to as an intervention main path. The intervention main path may be performed to address one or more specified well symptoms. The well for which the intervention is being performed may be associated with one or more well conditions, such as well completion, well trajectory, and well operational data. One or more objectives for the well intervention may be specified. In some aspects, a contingency path may be followed when the main path is unsuccessful.

According to certain aspects, historical well intervention information may be collected. The historical well intervention information may include the information about previous well interventions, and may be collected from multiple users of well intervention system. The collected historical intervention information may be used to maintain statistics on the well intervention. For example, intervention main paths and contingency paths may be associated with respective intervention objectives, well conditions, a count of the number of times the path was used (e.g., successfully), a probability of success, a cost, and/or a duration. The well conditions may include well completion and well trajectory information. The well condition information may include a hole survey of the well, wellbore conditions (e.g., temperature, pressure, presence or amount of corrosive gases such as hydrogen sulfide and carbon dioxide), the type of well completion, a size of a well completion, a weight of a well completion, and/or information regarding downhole components, such as nipples, packers, artificial lift equipment, a sub-surface safety valve (SSSV), and/or other equipment or well condition information such as high producing well information, injector well information. The historical information and statistics may be used for automatic well intervention plan generation.

According to certain aspects, an automatic well intervention plan generation system may receive input from a user regarding information for a well intervention. The automatic well intervention plan generation system may match the information input by the user to information associated with well interventions in the historical information in order to generate a well intervention plan to recommend to the user. In some aspects, the information input from the user is sent to template service to request a predefined template from a database of templates created by domain experts, and information is also sent to a plan generator that creates a plan based on the historical information and statistics.

In some aspects, the system selects a well intervention plan from the database that most closely matches the intervention objectives and well conditions input by the user. In some aspects, the system selects the well intervention plan from the database based on one or more user preferences input by the user. In some aspects, the system identifies multiple plans in the database that equally match the intervention objectives and well conditions input by the user. In this case, the system may select the well intervention plan from the multiple well intervention plans based on a criteria, such as a well intervention plan having the highest count, shortest duration, lowest cost, and/or other criteria. In some aspects, the system further selects a contingency path based on the historical and statistical information.

In some aspects, a physics model may be used to model the well to aid in selection of a well intervention plan for the well. In some aspects, the physics model may be used to select a subset of well intervention plans (e.g., by filtering our one or more well intervention plans from the database based on the modeling), and the system may then select the well intervention plan from the subset, based on the matching of the intervention objections and well conditions and/or based on the criteria.

In some aspects, the system generates the well intervention plan further based on information about available equipment for the performing the well intervention operations. The equipment information may include equipment procurement information, equipment inventory information, and/or equipment maintenance information. In some aspects, the types, or efficacy, of well interventions, well intervention technologies, and/or well intervention operations may be limited based on the available equipment. In some aspects, the equipment information may be used to select a subset of well intervention plans from the database, and the well intervention plan may then be selected from the subset of well intervention plans based on the historical information of statistics associated with the subset of well intervention plans.

In some aspects, as mentioned above, a software tool may be used in creating a well intervention plan. In some aspects, use of an interactive intervention plan tool may improve the efficiency of intervention planning, provide a standardized method for creating and selecting well intervention plans, and increase the likelihood of a successful well intervention.

The various intervention operations and associated intervention technologies for a well intervention plan may be associated with a probability of success or failure. In certain current systems, the user determines the respective probability of success of the intervention operations and technologies based on the user's own knowledge and expertise. The user may input the estimated probabilities in the well intervention planning tool. In this case, the user of the well intervention planning tool may be required to be experienced in well intervention planning. Further, even such estimations of the probability of success of the well intervention operations and technologies by the experienced user may still be subjective, time consuming, and subject to human error. Incorrect estimations of the probabilities of success may lead to a poor well intervention plan, in turn leading to increased well intervention failure risk and associated costs.

According to certain aspects, a predictive model may be used to predict the probability of success for intervention plans, operations, and technologies. In some aspects, the predictive model is a statistical model. In some aspects, the predictive model is a machine learning model.

In some aspects, the predictive model is trained based on historical information of previous well interventions. The historical information may be collected from all users of the well intervention planning system. In some aspects, a machine learning model uses binary classification to predict the probability of success of the well intervention operations and technologies. In some aspects, the machine learning model uses a Random Forest algorithm. The probability of risk may be used as a key performance indication in the well intervention planning for the selection of well intervention operations and technologies. In some aspects, using the predictive model, the well intervention planning may be improved even for users without well intervention planning experience. With the predictive model, the prediction of the probability of success of the well intervention operations and technologies may be more objective, more accurate, and more efficient.

In some aspects, the predictive probability of success for well intervention involves data collection, pre-processing and feature labeling of the collected data, training and evaluation of the predictive model based on the labeled data, deployment of the predictive model, and user interaction with the predictive model. The following description includes embodiments of the best mode presently contemplated for practicing the described implementations. This description is not to be taken in a limiting sense, but rather is made merely for the purpose of describing the general principles of the implementations. The scope of the described implementations should be ascertained with reference to the issued claims.

### Example Automated Well Intervention Plan Generator

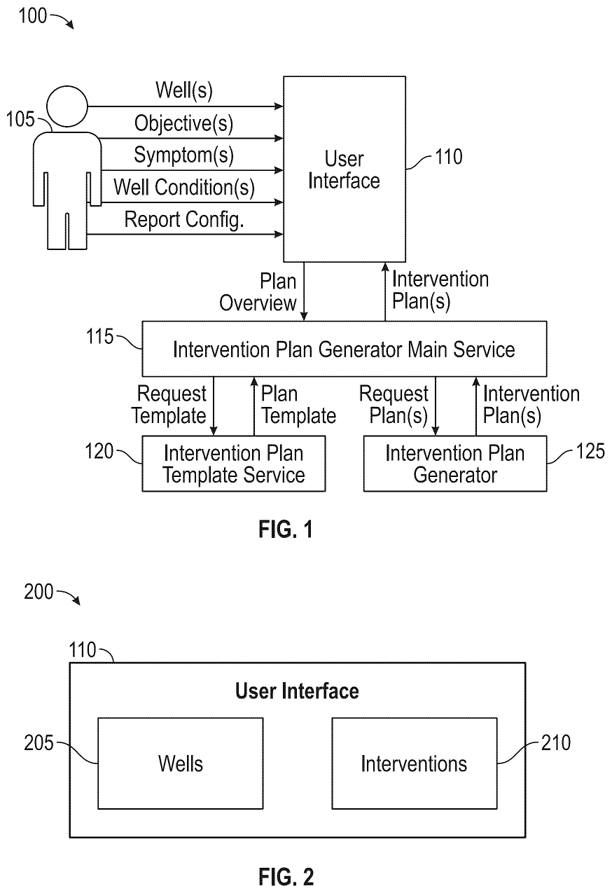

FIG. 1 depicts an example automatic well intervention plan generator system 100.

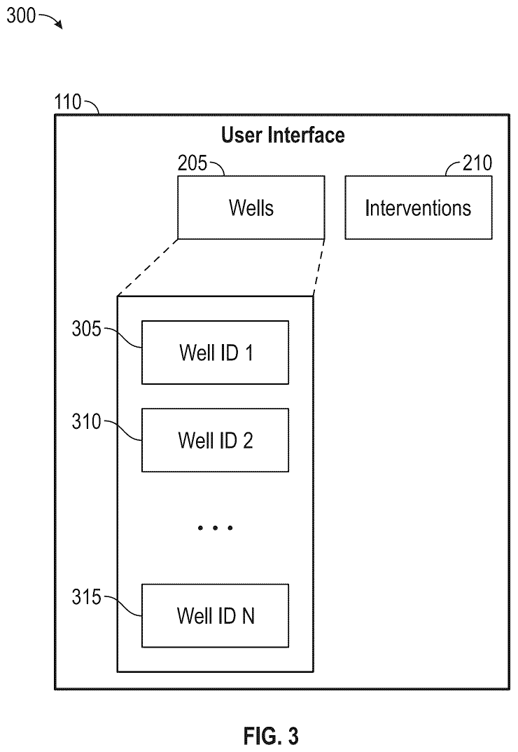

As shown, a user 105 of the automatic well intervention plan generator system 100 may input information to an intervention plan generator main service 115 via a user interface 110. For example, the user 105 may input information used by the automatic well intervention plan generator system 100 to automatically generate a well intervention plan. As shown in FIG. 1, and as described in more detail herein with respect to FIGS. 2-11, the information input by the user 105 to the intervention plan generator main service 115 via a user interface 110 may include well selection information, intervention objectives, well symptoms, well conditions, report configuration, and/or other information.

FIGS. 2-13 illustrate example displays of the user interface 110 allowing a user 105 to operate the automatic well intervention plan generator system 100. It should be understood, however, that the examples shown in FIGS. 2-13 are merely illustrative examples of the user interface 110. In some aspects, the displays in FIG. 2-13 include selectable options. The selectable options may be in the form buttons. When the user 105 selects (e.g., presses) one of the buttons, the user interface 110 may display a new screen, a drop down menu, or a pop-up window with information associated with the selectable option. Further, while illustrative examples provide for selectable options, in some cases the user 105 may directly input information to the user interface 110, for example, by manually entering or typing information, rather than selecting a provided option. In addition, while certain information are described information input in fields, it should be understood that in other examples the information may be provided as selectable options. Further, while FIGS. 2-13 illustrate various user inputs and selections, in certain aspects, one or more of the inputs may be automated. For example, the information about well conditions may be collected by sensors and provided to the system, and the well selection and the intervention objectives may be automatically determined, selected, and/or defined by the system (i.e., without user input and/or with minimal user input).

FIG. 2 depicts an example home display 200 of the user interface 110. As shown, the home display 200 may include a selectable option for wells 205 and a selectable option for interventions 210.

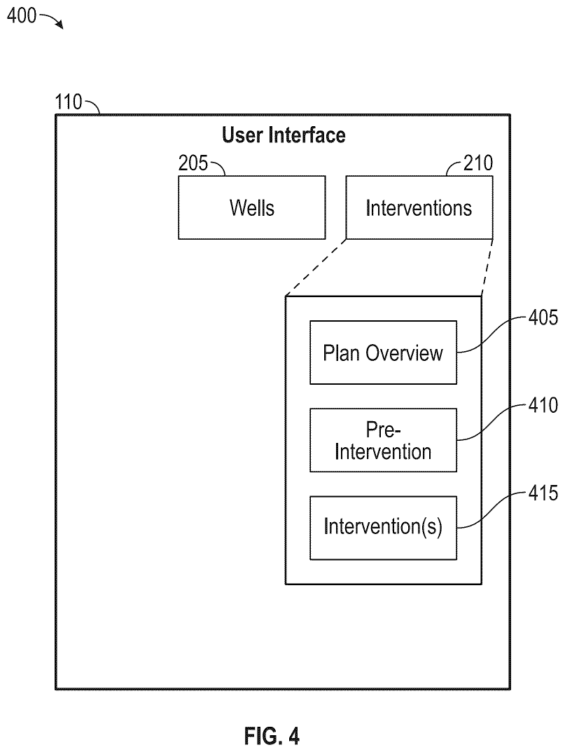

In the some aspects, the information input by the user 105 includes a well selection for the intervention. For example, the user 105 may select the selection option for wells 205 providing a list of one or more wells that the user 105 may select for intervention. FIG. 3 depicts an example well selection display 300 of the user interface 110. As shown, the well selection display 300 may include a list of wells. The wells may be associated with well identifiers (IDs). The list of wells may be selectable. For example, the list may include a selectable option for well ID 1 305, a selection option for well ID 2 310, . . . , and so on for N one or more wells until a selectable option for well ID N.

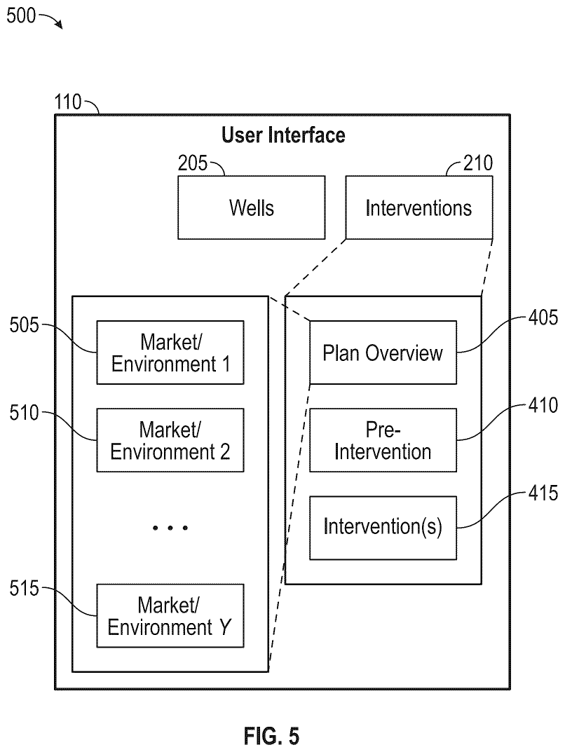

After selecting a well, the user 105 may begin inputting information enabling the automatic well intervention plan generator system 100 to automatically generate a well intervention plan for the selected well. In the illustrative example, the user 105 may select the selectable option for well intervention planning 210. FIG. 4 depicts an example well intervention display 400 of the user interface 110. As shown, the well selection display 400 may include a selectable option for inputting plan overview information 405, a selectable option for inputting pre-intervention information 410, and a selectable option for generating one or more well intervention plan(s) 415 for the selected well.

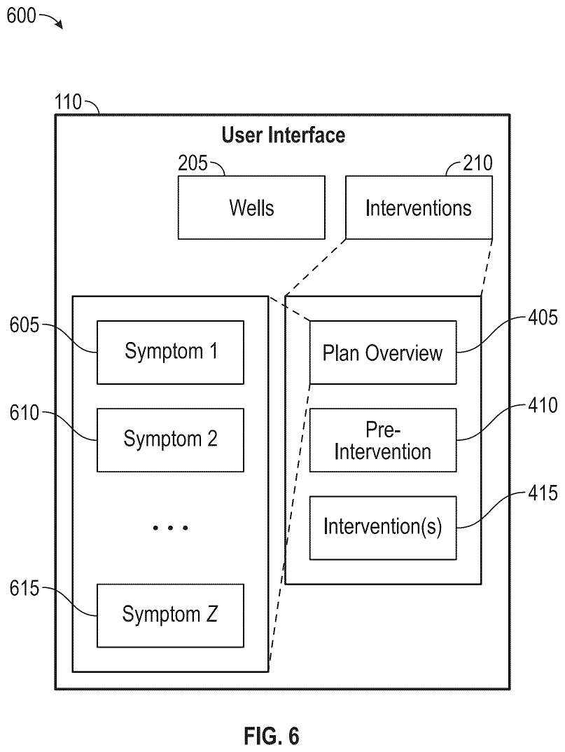

In some aspects, the plan overview information includes intervention objectives. In the illustrative example, in response to the user 105 selecting the selectable option for plan overview 405, the user 105 may be provided a list of selectable options for a market and/or environment. FIG. 5 depicts an example plan overview display 500 of the user interface 110. In one example, as shown in FIG. 5, the user 105 may be provided selectable options for Y markets and/or environments, including the selectable option for the market and/or environment 1 505, the market and/or environment 2 510, and so on until the market and/or environment Y 515. The markets may be geographic regions, countries, and/or other market options. The environments may include whether the well is a land well or an offshore well, such as whether the environment is deep water, offshore, remote, platforms, high-end land work, high volume land work, and/or other environments.

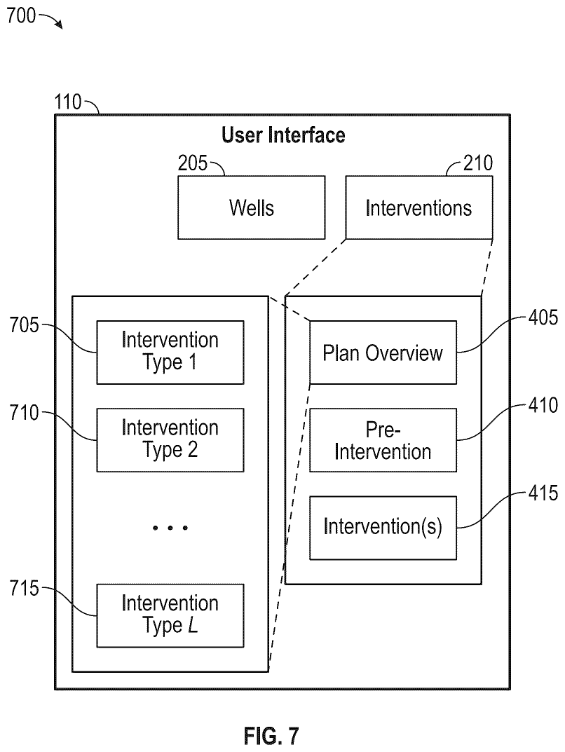

In some aspects, the plan overview information includes well symptoms to be addressed by the well intervention. In the illustrative example, in response to the user 105 selecting the selectable option for plan overview 405, the user 105 may be provided a list of selectable options for well symptoms. Alternatively, the list of selectable options for well symptoms may be provided after the user 105 selects the market(s) and/or environments. Alternatively, the list of selectable options for market(s) and/or environments may be provided after the user 105 selects the well symptoms. Alternatively, the list of selectable options for well symptoms may be provided together with the selections options for the market(s) and/or environments. FIG. 6 depicts another example plan overview display 600 of the user interface 110. In one example, as shown in FIG. 6, the user 105 may be provided selectable options for Z well symptoms, including the selectable option for the symptom 1 605, the symptom 2 610, and so on until the symptom Z 615. The well symptoms may include various types of well symptoms. Some non-limiting illustrative examples include skin Increase, sleeve not functioning, water cut increase, flow reduction, annulus pressure build up, apparent, asphaltene deposits predicted, caliper log reduction, camera evidence of obstruction, cannot function accessory, cannot Rih, declining production, deposition in surface equipment, dogleg severity high, downhole pressure change, etc.

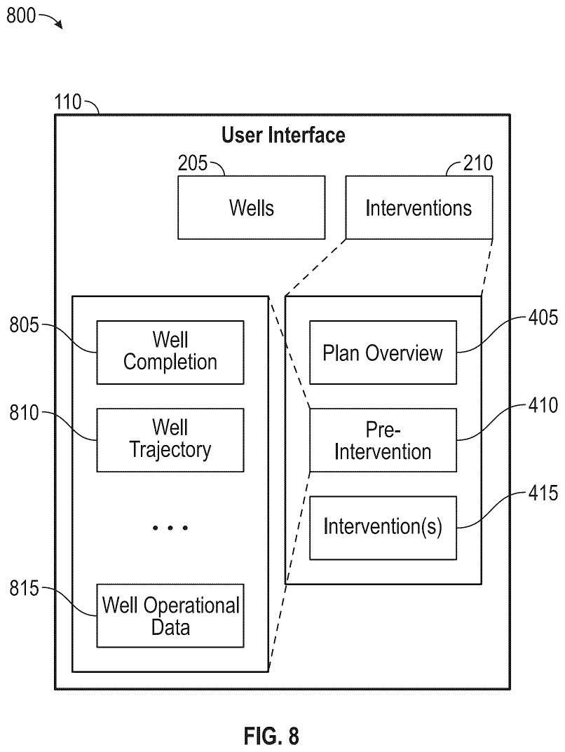

In some aspects, the plan overview information includes intervention types. In the illustrative example, in response to the user 105 selecting the selectable option for plan overview 405, the user 105 may be provided a list of selectable options for well intervention types. Alternatively, the list of selectable options for well intervention types may be provided after the user 105 selects the market(s) and/or environments and/or selects the well symptoms. Alternatively, the list of selectable options for market(s) and/or environments and/or the well symptoms may be provided after the user 105 selects the well intervention types. Alternatively, the list of selectable options for well intervention types may be provided together with the selections options for the market(s) and/or environments and/or the well symptoms. FIG. 7 depicts another example plan overview display 700 of the user interface 110. In one example, as shown in FIG. 7, the user 105 may be provided selectable options for L well intervention types, including the selectable option for the intervention types 1 705, the intervention types 2 710, and so on until the intervention types L 715. The well intervention types may include various well intervention types. Some non-limiting illustrative examples include sand consolidation, sand inflow evaluation, sand production prevention, sand screen repair, barrier diagnosis, buckled tubing, deformed tubing, cement evaluation, debris in well, debris on top of completion accessory, etc.

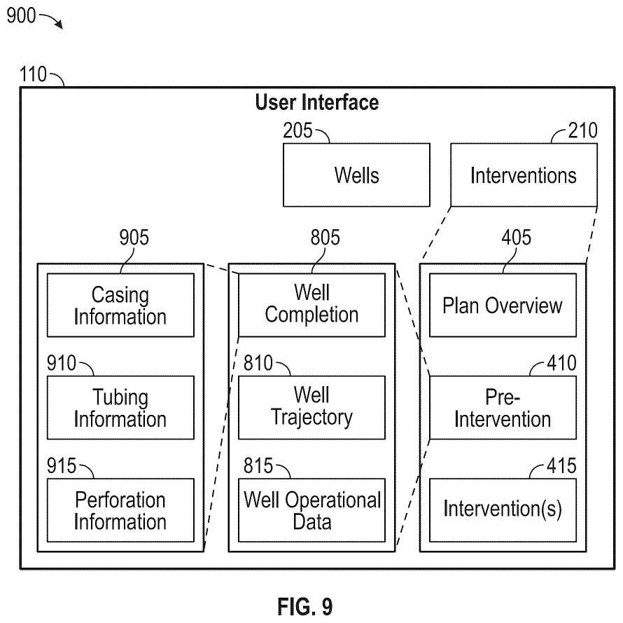

In some aspects, the pre-intervention information includes well completion information, trajectory information, and/or operational data information. FIG. 8 depicts an example pre-intervention display 800 of the user interface 110. In the illustrative example, the user 105 may select the selectable option for pre-intervention information 410, the user may be provided a selectable option for completion information 805, a selectable option for trajectory information 810, and a selectable option for operational data information 815.

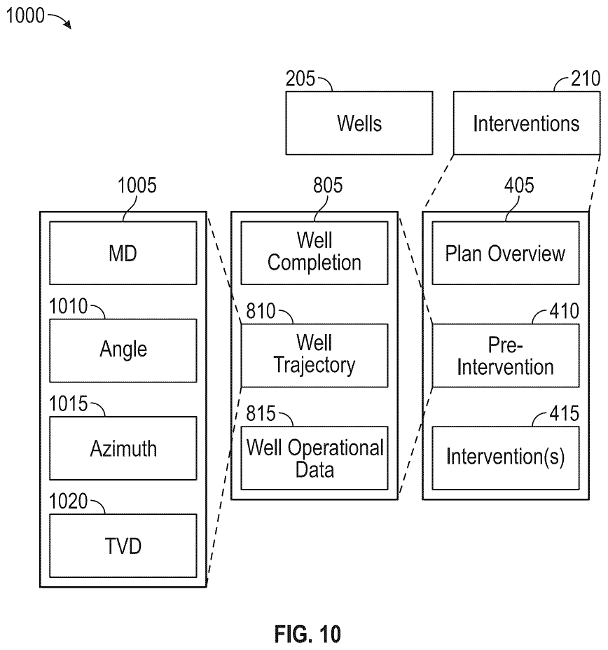

In some aspects, the well completion information includes completion information about the selected well. In some aspects, the well completion information includes downhole equipment information, artificial information, fluids information, and/or tubular information about the selected well. In some aspects, in response to the user 105 selecting the selectable option for well completion information 805, the user 105 may be provided a list of selectable options for inputting downhole equipment information, artificial information, fluids information, and/or tubular information about the selected well. In the illustrative example, in response to the user 105 selecting the selectable option for well completion information 805 (or additionally, in response to select a selectable sub-option for tubulars information), the user 105 may be provided a set of fields for inputting well completion information, such as casing information, tubing information, and/or perforation information. FIG. 9 depicts another example pre-intervention display 900 of the user interface 110. In one example, as shown in FIG. 9, the user 105 may be provided fields for inputting casing information 905, fields for inputting tubing information 910, and/or fields for inputting perforation information 915. The fields for inputting casing information 905 may include fields for inputting a starting and ending measured depth (MD) of the casing, a field for inputting an outer diameter (OD) of the casing, a field for inputting a weight of the casing, and/or a field for inputting an inner diameter (ID) of the casing. The fields for inputting tubing information 910 may include fields for inputting a starting and ending measured depth of the tubing, a field for inputting an outer diameter of the tubing, a field for inputting a weight of the tubing, and/or a field for inputting an inner diameter of the tubing. In some aspects, the fields may include fields for inputting casing thickness and/or tubing thickness. The fields for inputting perforation information 915 may include, for each perforation, a field for inputting a perforation name, a field for inputting a top measured depth, and a field for inputting a bottom measured depth. The well completion information may further include one or more fields for inputting other completion information (e.g., miscellaneous completion information). In some aspects, the well completion information includes information indicated a case hole or an open hole. In some aspects, a visualization (e.g., a graphical image or model) of the well completion may also be displayed.

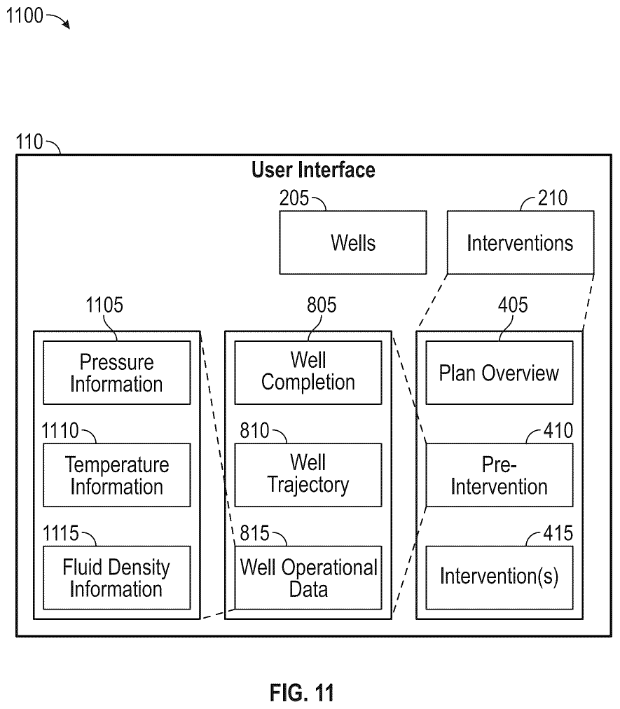

In some aspects, the well trajectory information includes trajectory information about the selected well. In the illustrative example, in response to the user 105 selecting the selectable option for well trajectory information 810, the user 105 may be provided a set of fields for inputting well trajectory information, such as for one or more measurement points, a measured depth, a well angle, an azimuth, and a true vertical depth (TVD). FIG. 10 depicts another example pre-intervention display 1000 of the user interface 110. In the illustrative example, as shown in FIG. 10, the user 105 may be provided fields for inputting measured depth 1005, fields for inputting angle 1010 at the measured depth, fields for inputting azimuth 1015 at the measured depth, and fields for inputting TVD at the measured depth. In some aspects, the well trajectory information includes information indicating the well is a vertical well, a horizontal well, or a deviated well. In some aspects, a visualization (e.g., a graphical image or model) of the well trajectory may also be displayed.

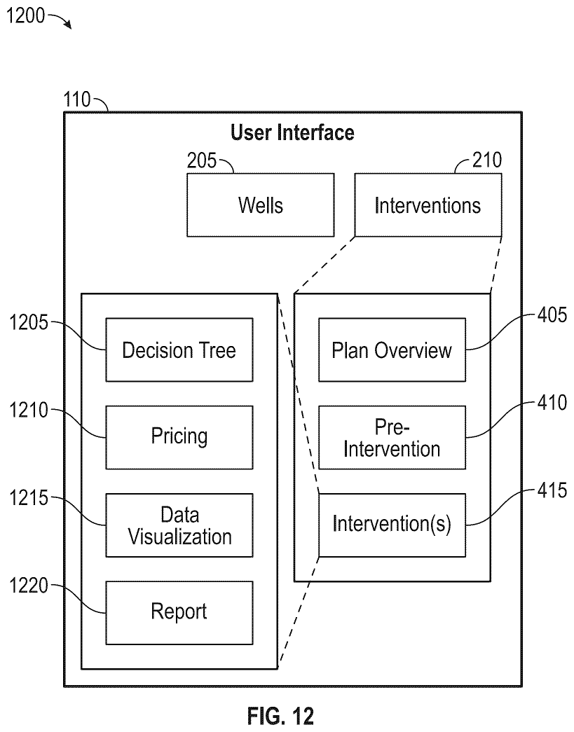

In some aspects, the well operational information includes operational data information about the selected well. In some aspects, the operational data information includes pressure, temperature, and/or fluid density information about the selected well. In some aspects, in response to the user 105 selecting the selectable option for well operational data information 815, the user 105 may be provided a set of fields for inputting well operational data information. FIG. 11 depicts another example pre-intervention display 1100 of the user interface 110. In one example, as shown in FIG. 11, the user 105 may be provided fields for inputting pressure information 1105, fields for inputting temperature information 1110, and/or fields for inputting fluid density information 1115. In some aspects, the well operational information includes fields for inputting a minimum restriction of the well, fields for inputting a total depth (TD), and/or fields for inputting a sea bottom depth. In some aspects, the fields for inputting pressure information 1105 include a maximum pressure at the total depth. In some aspects, the fields for inputting temperature information 1110 include fields for inputting a maximum temperature at the total depth, fields for inputting surface temperature, and/or fields for inputting sea bottom temperature. In some aspects, the fields for inputting fluid density information 1115 includes fields for inputting a fluid of the well and/or fluids for inputting a fluid density of the fluid. In some aspects, the well operational information includes fields for indicating whether an acid gas is present and fields for indicating a concentration of the acid gas.

In certain systems, the intervention plan for the selected well is created manually by the user 105. For example, in some systems, in response to selecting the selectable option for well interventions 415, the user 105 may be required to input each intervention technology(ies) (e.g., for evaluation, perforation, development, cement evaluation, ultrasonic logging tools, plug, milling, cleanout, etc.) and associated interventions, symptoms, and tools to manually generate an intervention plan. According to aspects of the present disclosure, that will be discussed in more detail below with respect to the FIGS. 1 and 14-16, the automatic well intervention plan generator system 100 may automatically generate the well intervention based on the intervention objectives and well conditions.

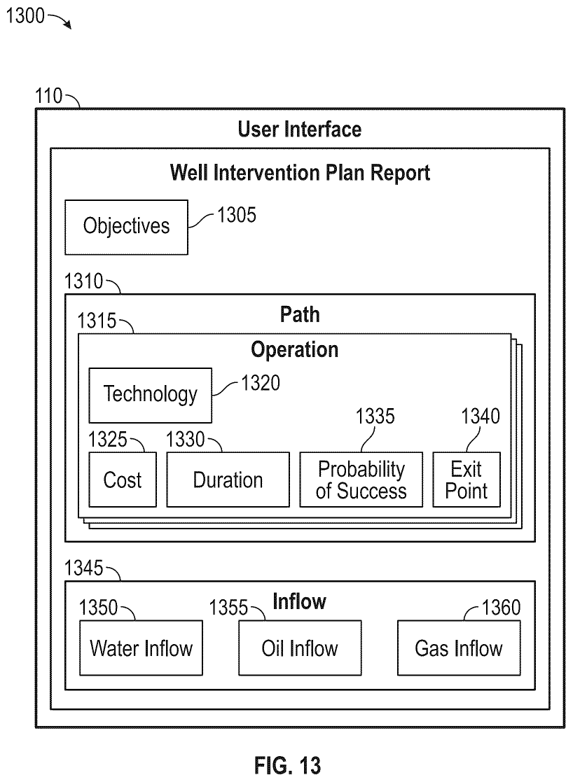

The well intervention plan may provide information to the user 105, such as a main path, one or more contingency paths, decision tree information, intervention operation duration, success probabilities, pricing information, data visualization, and reporting. In the illustrated example, in response to the user 105 selecting the selectable option for well interventions 415, a well plan may be automatically generated and the user 105 may be provided with a list of selectable options. FIG. 12 depicts an example intervention display 1200 of the user interface 110. As shown in FIG. 12, the intervention display 1200 includes a selectable option for decision tree information 1205, a selectable option for pricing information 1210, a selectable option for data visualization 1215, and/or a selectable option for a report 1220. In response to the user 105 selecting the selectable option for pricing information 1210, the user 105 may be provided with pricing information associated with a cost of executing the well intervention plan. The selectable option for a report 1220 may allow the user 105 to select one or more options for configuring a report of the well intervention plan.

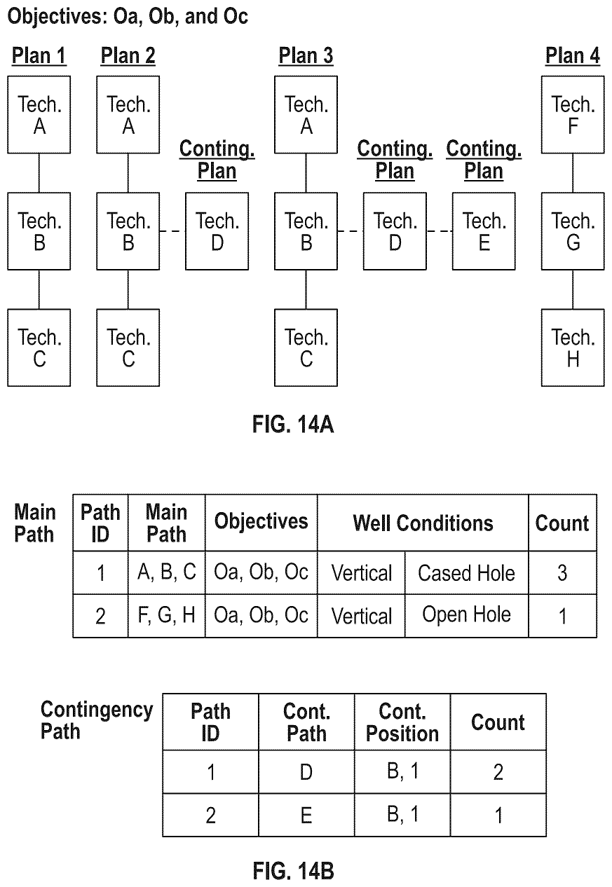

FIG. 13 illustrates a well intervention plan report display 1300 of the user interface 110 for an example well intervention plan report. As shown, a well intervention plan report may display the intervention objectives 1305, the path information 1310, and inflow information 1345. The path information 1310 may include one or more operations 1315. For each operation 1315, the path information 1310 may include the associated technology 1320, an estimated cost 1325 of the operation 1315, and estimated duration 1330 for the operation 1315, an estimated probability of success 1335 of the operation 1315, and/or an exit point 1340 for the operation 1315. The exit point 1340 may indicate a realized cost and/or duration at which the operation may be aborted. In some cases, a contingency path may be followed when an operation is aborted. The inflow information 1345 may include an estimated, predicted, or simulated inflow values for one or more fluids associated with the well. As shown in FIG. 13, the inflow information 1345 may include water inflow 1350, oil inflow 1355, and/or gas inflow 1360 information. The inflow information may allow an evaluation of inflow without the planned well intervention compared to inflow after the well intervention. In some aspects, the well intervention plan may be implemented, or not, based, at least in part, on the difference in the inflows.

As mentioned above, the automatic well intervention plan generator system 100 automatically generates the well intervention plan for a selected well based on the objectives and well conditions information input by the user 105 via the user interface 110 to the intervention plan generator main service 115. In some aspects, the user 105 may further input one or more user preferences for the intervention plan generation. Referring back to the FIG. 1, the intervention plan generator main service 115 may feed the user input to the intervention plan template service 120 to request one or more intervention plan templates. The intervention plan template service 120 of the automatic well intervention plan generator system 100 may maintain (e.g., locally or have remote access to) a database of well intervention plans. In some aspects, well intervention plans in the database include well intervention plans predefined by domain experts. In some aspects, a well intervention plan may be selected from the intervention plan template service based on the matching of the well conditions and intervention objectives and/or the criteria.

The intervention plan generator main service 115 may also feed the user input to the intervention plan generator 125 to request one or more intervention plans. In some aspects, the intervention plan generator 125 uses historical information and/or statistics associated with the well intervention plans to generate a well intervention plan. In some aspects, the well intervention plan historical information is collected across many users of the intervention plan generator main service 115, which may be associated with many different wells. In some aspects, the historical information includes operational data, such as data collected by one or more logging tools. In some aspects, the well intervention plan template service associates well intervention plans in the well intervention plan database with statistics, intervention objectives, operational data, and/or well conditions.

According to certain aspects, the historical information of the well intervention plans are associated with other information, such as the intervention objectives and/or well conditions (e.g., completion information, trajectory, and/or operational data). In addition, other criteria may be associated with the historical information, such as duration, cost, count (number of times the plan was used, or successfully used), and/or user preferences. Based on the associations, a current intervention plan may be generated.

In some aspects, the intervention plan generator main service 115 generates, for example using a machine learning model, a well intervention plan based on the historical information.

In some aspects, two well intervention plans are output by the intervention plan generator main service 115 to the user 105. The system may provide the user with a recommended expert-created well intervention plan from the intervention plan template service and also with a recommend well intervention plan from the intervention plan generator based on the statistical information associated with the database of collected well information plans by the intervention plan generator main service 115 across user and wells.

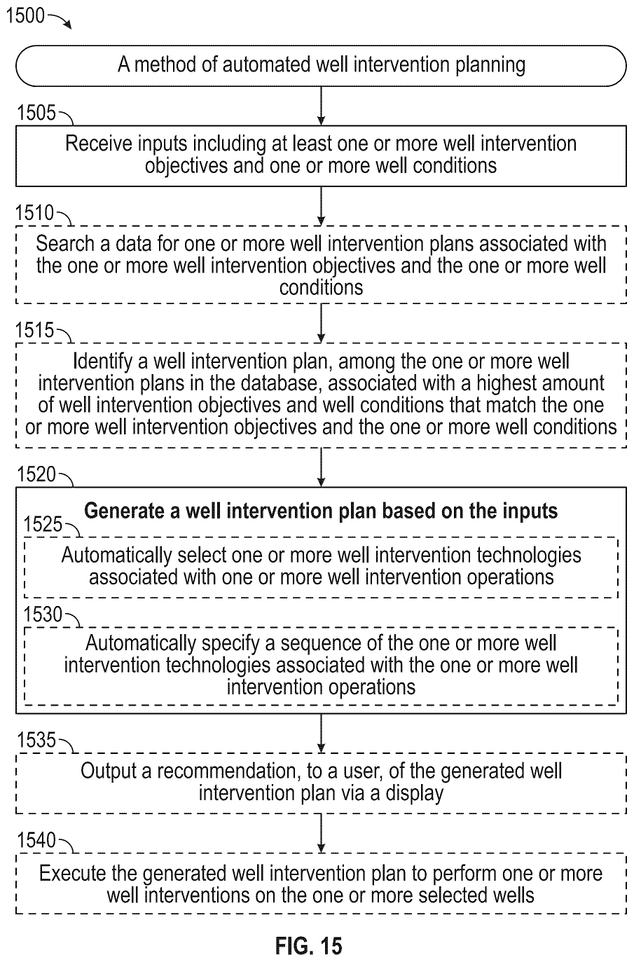

FIGS. 14A-14B depict an illustrative example of collected historical well intervention plan information and associated statistics. It should be understood, that the historical well intervention plan information may include fewer or more plans than those illustrated. In addition, plans may include the historical well intervention plan information for plans associated with many different objectives, different numbers of objectives, many different main paths, different numbers of main paths, many different contingency path, different numbers of contingency paths, many different well conditions, and/or many different numbers of well conditions, that are in addition to or alternatively to those illustrated in FIGS. 14A-14B.

FIG. 14A depicts example collected historical well intervention plan information. As shown in FIG. 14A, the collectable historical well intervention plan information includes multiple well intervention plans—Plan 1, Plan 2, Plan 3, Plan 4. In the illustrative example, the well intervention plans are associated with the intervention objectives Oa, Ob, and Oc. In the illustrative example, well intervention Plan 1 includes a “main path” using the technologies A, B, and C. For example, technology A may be associated with a first intervention operation (e.g., such as an operation 1315) in the well intervention plan, technology B may be associated with a second intervention operation, and technology C may be associated with a third intervention operation. As shown in FIG. 14A, Plan 2 and Plan 3 also use the main path A, B, C. As also shown in FIG. 14A, the Plan 2 includes a contingency plan, where the technology D is used as a contingency for the technology B. Technology D may be associated with a fourth intervention operation. The contingency plan may be followed when the main path is unsuccessful, such as when the technology point reaches an exit point based on the actual cost and/or duration. As shown in FIG. 14A, the Plan 3 uses the technology D and additionally the technology E as a second contingency. The technology E may be associated with a fifth intervention operation. As shown in FIG. 14A, the Plan 4 uses a different main path with the technologies F, G, and H. The technology F may be associated with a sixth intervention operation, the technology G may be associated with a seventh intervention operation, and the technology G may be associated with an eighth intervention operation.

FIG. 14B depicts example statistical associations of the collected historical well intervention plan information of FIG. 14A. As shown, the main path A, B, C used in the Plans 1, 2, and 3 may have a first assigned path ID (Path ID 1) and the main path F, G, H used by the Plan 4 may have a second assigned path ID (Path ID 2). Both the path ID 1 and the path ID 2 are associated with the set of objectives Oa, Ob, and Oc. The path ID 1 is associated with the well conditions “vertical” and “cased hole” and the path ID 2 is associated with the well conditions “vertical” and “open hole.” The path ID 1 is further associated with a count of three, indicating the main path of path ID 1 was used for three intervention plans and the path ID 2 is associated with a count of one indicating the main path of path ID 2 was used a single time (for Plan 4).

In addition, a first and second contingency path ID may be assigned. The first contingency path ID is associated with the technology D, a contingency position {B,1}, indicating the technology D is a contingency to technology B, and a count of 2. The second contingency path ID is associated with the technology E, a contingency position {B,1}, and a count of one.

The historical information and statistics may be used to provide a well intervention plan (and/or template) to the intervention plan generator main service 115 based on the objectives and well conditions input by the user 105. For example, a well intervention plan may be selected from the database that is associated with objectives and well conditions that most closely matches the objectives and well conditions input by the user 105. In some aspects, where multiple well intervention plans match, a well intervention plan with the highest count among the equally matching well intervention plans may be selected. In some aspects, the well intervention plan may be further selected based on configured user preferences for selecting a well intervention plan template from the database. In some aspects, the well intervention plan may be selected further based on cost, risk of operation (e.g., likelihood of success), and duration. In some aspects, the selection may be based on weights and/or thresholds, balancing the level of matching objectives and well conditions with the user preferences, cost, risk, and/or duration.

Referring back the example illustrated in FIGS. 14A-14B, for a well intervention having the objective Oa and the well conditions “vertical well” and “cased hole”, the automated well intervention planning system 100 may search the data and find that both the main path ID 1 and the main path ID 2 match the objective, and that the well conditions are fully matched for the main path ID 1, but the well conditions are only partially matched for the main path ID 2 (e.g., main path ID 2 is for “open hole”). In this case, the automatic well intervention plan generator system 100 may select the main path ID 1 for the well intervention plan. Alternatively, if the main path ID 2 was also for “cased hole”, then both the main path ID 1 and the main path ID 2 would be fully matched. In that case, the automatic well intervention plan generator system 100 may select the main path ID 1 based on the main path ID 1 having the higher count. In some aspects, the selection may be based on other criteria, such as the user preferences, an associated duration, and/or an associated cost of the well interventions associated with the main path ID 1 and the main path ID 2.

In some aspects, for a contingency path recommendation, the automatic well intervention plan generator system 100 may select the contingency path based on the criteria. For example, referring again to the example illustrated in FIGS. 14A-14B, for the technology B, the automatic well intervention plan generator system 100 may recommend the contingency path D based on the contingency path D having the highest count.

In some aspects, historical information of previous well intervention plans may be pre-processed. For example, missing values may be added (e.g., imputed), outliers may be removed, units may be standardized, and/or data may be categorized.

In some aspects, a well intervention is considered successful if the intervention achieves the input objective. In some aspects, the user 105 may input feedback on a well intervention plan indicating the success of the plan.

### Example Operations for Automated Well Intervention Planning

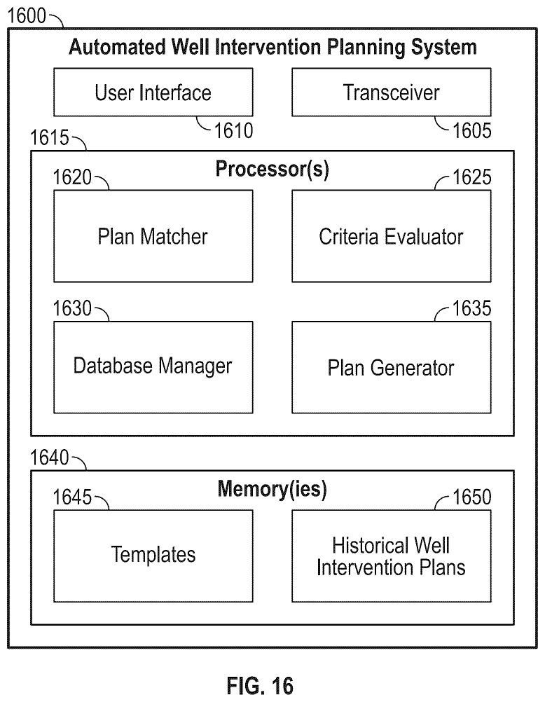

FIG. 15 is a flow diagram depicting an example operations 1500 for automated well intervention planning.

As shown, the operations 1500 may include, at operation 1505 receiving inputs. The inputs include at least one or more well intervention objectives and one or more well conditions. In some aspects, the inputs further include a selection of one or more wells for generating one or more well intervention plans. In some aspects, the well one or more intervention objectives inputs include at least one of: one or more target markets, one or more well environments, one or more well symptoms, or one or more well invention types. In some aspects, the one or more well conditions inputs includes at least one of: well completion information, well trajectory information, or well operational information. In some aspects, the well completion information includes at least one of: casing information, tubing information, perforation information, or whether the well is a cased hole or an open hole. In some aspects, the well trajectory information includes at least one of: whether the well is a horizontal well, a vertical well, or a deviated well; an angle at a measured depth; an azimuth at the measured depth; or a true vertical depth at the measured depth. In some aspects, the well operational information includes at least one of: pressure information, temperature information, or fluid density information. In some aspects, the inputs further include well equipment information comprising at least one of: equipment procurement information, equipment inventory information, or equipment maintenance information. In some aspects, the inputs are received from user via a user interface.

As shown, the operations 1500 may include, at operation 1520 generating a well intervention plan based on the inputs. In some aspects, the operations 1500 may include, at operation 1510, searching a database for one or more well intervention plans associated with the one or more well intervention objectives and the one or more well conditions. In some aspects, the operations 1500 may include, at operation 1515, identifying a well intervention plan, among the one or more well intervention plans in the database, associated with a highest amount of well intervention objectives and well conditions that match the one or more well intervention objectives and the one or more well conditions. In some aspects, multiple well intervention plans in the database having an equal amount of matching well intervention objectives and well conditions are identified at operation 1515. In some aspects, the operations 1500 may include selecting the well intervention plan of the multiple well intervention plans that satisfies a criteria. In some aspects, the criteria comprises at least one of: the well intervention plan associated with a highest count among the multiple well intervention plans, the well intervention plan associated with a shortest duration among the multiple well intervention plans, the well intervention plan associated with a lowest cost among the multiple well intervention plans, or one or more user specified preferences. In some aspects, the operations 1500 may further include using a physics-based model of the well to select a subset of the one or more well intervention plans in the database. In some aspects, identifying the well intervention plan at operation 1515 is from among the subset of the one or more well intervention plans. In some aspects, generating the well intervention plan at operation 1520 is further based on the identified well intervention plan. In some aspects, generating the well intervention plan at operations 1520 is further based on the equipment information input.

In some aspects, the operations 1500 may further include searching the database for one or more contingency well intervention plans based on the generated well intervention plan. In some aspects, the operations 1500 may further include generating a contingency well intervention plan based on the one or more contingency well intervention plans. In some aspects, the operations 1500 may further include identifying at least one contingency well intervention technology, associated with a well intervention operation, that is associated with at least one well intervention technology of the generated well intervention plan. In some aspects, multiple contingency well intervention technologies associated with the well intervention technology of the generated well intervention plan are identified. In some aspects, the operations 1500 may further include selecting a contingency well intervention technology of the multiple contingency well intervention technologies that satisfies a criteria.

In some aspects, generating the well intervention plan, at operation 1520, includes automatically selecting one or more well intervention technologies associated with one or more well intervention operations at operation 1525, and automatically specifying a sequence of the one or more well intervention technologies associated with the one or more well intervention operations at operation 1530.

As shown, the operations 1500 may include, at operation 1535 outputting a recommendation, to a user, of the generated well intervention plan via the display.

As shown, the operations 1500 may include, at operation 1540, executing the generated well intervention plan to perform one or more well interventions on one or more selected wells.

### Example System for Automated Well Intervention Planning

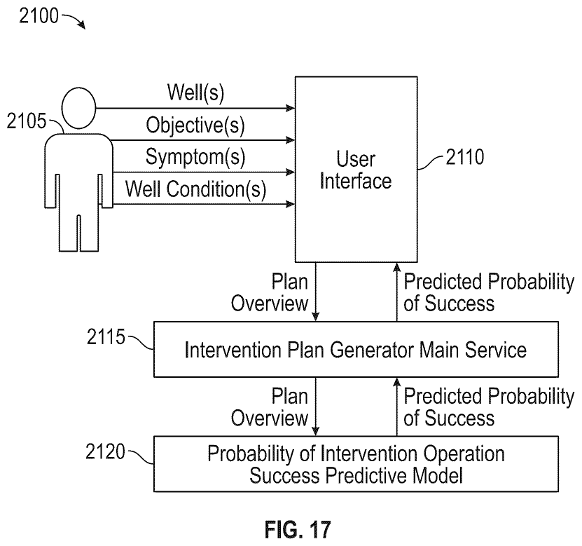

According to certain aspects, an automated well intervention planning system 1600 is provided, as shown in FIG. 16. The automated well intervention planning system 1600 may run on a single computing device or across multiple devices.

As shown, the automated well intervention planning system 1600 may include one or more user interfaces 1610 on the one or more devices comprising the automated well intervention planning system 1600 that allow a user to interact with the automated well intervention planning system 1600. The one or more user interfaces 1610 may be an example of the user interface 110 of FIG. 1. In some examples, the user interface(s) 1610 may include a graphical user interface (GUI) that display to a user and/or accepts touch screen inputs from the user. The user interface(s) 1610 may include one or more input/output (IOs) interfaces that allows one or more I/O devices (e.g., keyboards, displays, mouse devices, pen inputs, microphones, etc.) to connect to the automated well intervention planning system 1600. In some aspects, the user interface(s) 1610 are configured to receive user input, including intervention objectives, well conditions, and/or user preferences as described herein.

As shown in FIG. 16, the automated well intervention planning system 1600 may include a transceiver 1605 and one or more network interface(s). The transceiver 1605 and network interface(s) may allow the automated well intervention planning system 1600 to connect to a network (e.g., such as the Internet, a local area network (LAN), a wireless LAN (WLAN), a wireless wide area network (WWAN), Wi-Fi, etc.) and/or to communicate with other devices, such as to communicatively connect devices within the automated well intervention planning system 1600 and/or devices external to the automated well intervention planning system 1600. In some aspects, the transceiver 1605 and one or more network interface(s) may be used to collect historical well intervention plan information and statistics from multiple users of the automated well intervention planning system 1600.

As shown, the automated well intervention planning system may include a processing system including one or more processor(s) 1615. The one or more processor(s) 1615 may comprise one or more central processing units (CPUs). The CPU may have multiple processing cores. In some aspects, the processor(s) 1615 may include a plan matcher processor 1620 configured to search a database (e.g., in memory(ies) 1640) for well intervention plans matching input from the user (received via user interface 1610), such as the intervention objectives, well conditions, and/or user preferences. In some aspects, the processor(s) 1615 may include a plan criteria evaluator processor 1625 configured to evaluate the matching plan(s) found by the plan matcher processor 1620 based on one or more criteria, such as the count, associated duration, associated cost, or other criteria. In some aspects, the processor(s) 1615 may include a database manager processor 1630 configured to manage the templates 1645 and/or the historical well intervention plan information 1650. For example, the database manager processor 1630 may be configured to associate the template 1645 and/or the historical well intervention plan information 1650 with associated intervention objectives, well conditions, cost, duration, probability of success, count, and/or other user preference or criteria. In some aspects, the processor(s) 1615 may include a plan generator processor 1635 configured to recommend a well intervention plan to a user based on the plan matching and/or criteria evaluation.

The processing system may further include memory(ies) 1640 and/or storage(s), which may be local to the automated well intervention planning system 1600 or remote (e.g., cloud storage). The memory 1640 may represent a random access memory (RAM). The storage may be a disk drive, a combination of fixed or removable storage devices, such as fixed disc drives, removable memory cards or optical storage, network attached storage (NAS), or a storage area-network (SAN). The CPU may retrieve and execute programming instructions stored in the memory(ies) 1640. Similarly, the CPU may retrieve and store application data residing in the memory(ies) 1640. As shown in FIG. 16, the memory(ies) 1640 may store well intervention templates 1645 and associations of the templates to intervention objectives and well conditions. As shown in FIG. 16, the memory(ies) 1640 may store historical well intervention plan information 1650, which include associations of the well intervention plans to intervention objectives and well conditions and statistical information such as the counts.

### Example Well Intervention Planning System

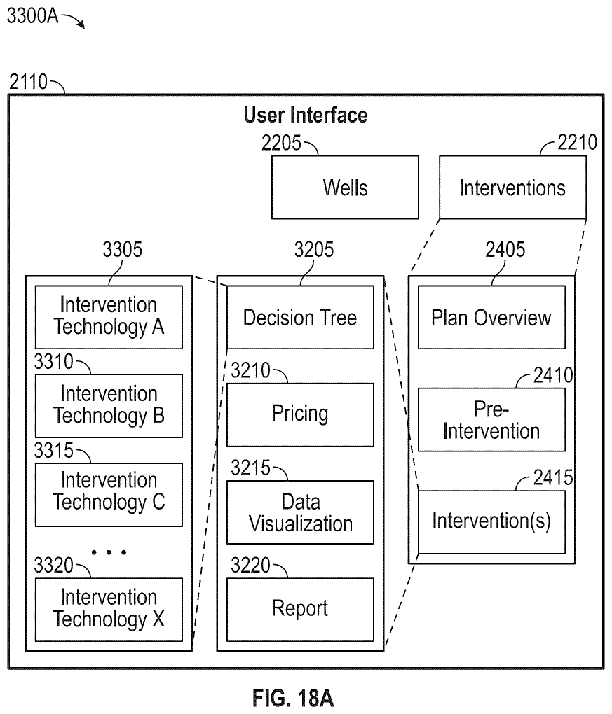

FIG. 17 depicts an example well intervention planning system 2100.

As shown, a user 2105 of the well intervention planning system 2100 may input information to an intervention plan generator main service 2115 via a user interface 2110. The information input by the user 2105 to the intervention plan generator main service 2115 via a user interface 2110 may include well selection information, intervention objectives, well symptoms, well conditions, and/or other information.

The user interface 2110 can provide displays analogous to the example displays of FIGS. 2-13 related to the Example Automated Well Intervention Plan Generator. As a result, the description thereof will not be repeated. It should be understood, however, that the examples shown in FIGS. 2-13 are merely illustrative examples of the user interface 2110.

Particularly, an example home display of the user interface 2110 is analogous to the home display 200 of FIG. 2. An example well selection display of the user interface 2110 is analogous to the well selection display 300 of FIG. 3. An example well intervention display of the user interface 2110 is analogous to the well intervention display of FIG. 4. An example plan overview display of the user interface 2110 can be analogous to the plan overview display of FIG. 5, the plan overview display of FIG. 6 or the plan overview display of FIG. 7. An example pre-intervention display of the user interface 2110 can be analogous to the pre-intervention display of FIG. 8, to the pre-intervention display of FIG. 9, to the pre-intervention display of FIG. 10, or to the pre-intervention display of FIG. 11. In some aspects, the user 2105 may add the intervention operations and technologies to a decision in order to plan the well intervention. In certain current systems, the user 2105 may further manually add a probability of success of each intervention operation. An example intervention display of the user interface 2110 can be analogous to the intervention display of FIG. 12.

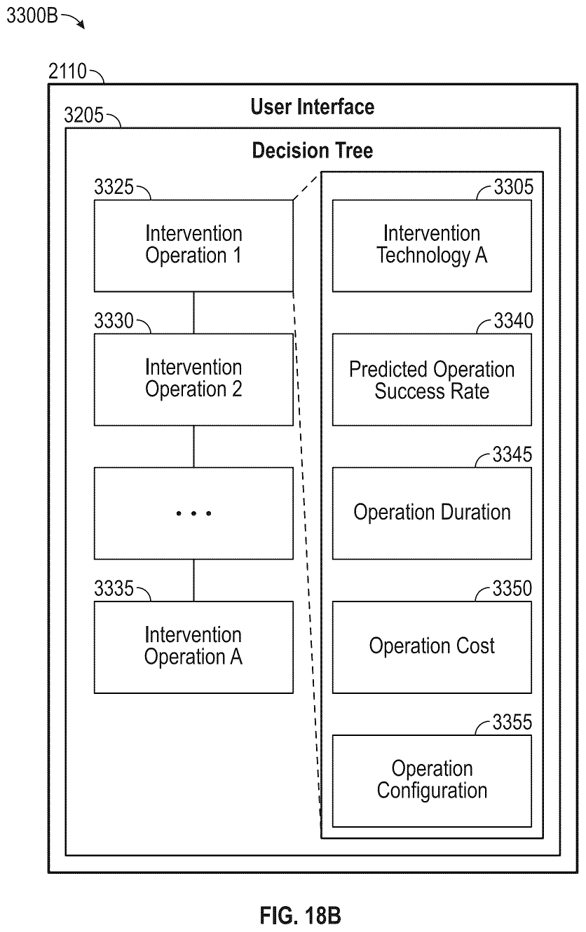

FIG. 18A illustrates a well intervention display 3300A of the user interface 2110 for an example well intervention plan decision tree. As shown, in response to the user 2105 selecting the selectable option for the decision tree information 3205, the user 2105 may be provided with a list of selectable options for creating a decision tree to plan the well intervention operations. In the illustrative example, the list of selectable options may include a list of intervention technologies including intervention technology A 3305, intervention technology B 3310, intervention technology C 3315, and so on until intervention technology X 3320. The user 2105 may use the decision tree to determine which intervention operations and technologies to include the final well intervention plan. The probability of success of the intervention operations may be a key parameter used in the decision making by the user.

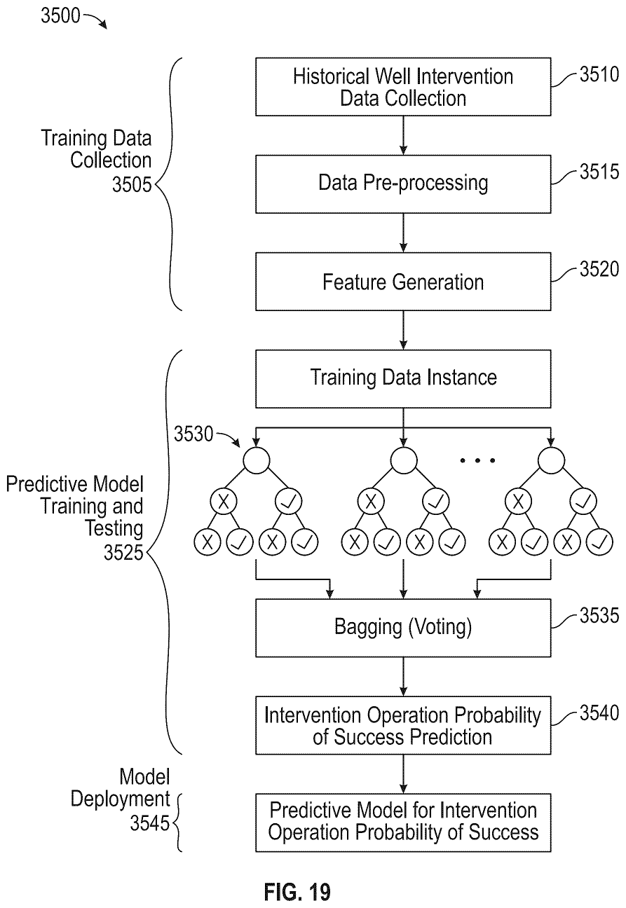

FIG. 18B illustrates a well intervention display 3300B of the user interface 2110 for the example well intervention plan decision tree. In response to the user 2105 selecting one or more of the selectable intervention technologies 3305-3320, intervention operations may be added to the well intervention display 3300B in a decision. As shown in the FIG. 18B, based on the selected intervention technologies, intervention 1 3325, intervention operation 2 3330, and so until intervention operation A 3335, may be added to the decision tree. In the illustrative example, the user 305 may select an intervention operation from the decision tree to input and/or view information associated with intervention operation. As shown in the FIG. 18B, in response to the user 305 selecting the selectable intervention operation 1 3325, the user 2105 may be provided with the information associated with the intervention operation 1 3325. As shown, the information may include the associated intervention technology (e.g., intervention technology A 3305 in the illustrated example), a predicted intervention operation success rate 3340, an intervention operation duration 3345, an intervention operation cost 3350, and/or an intervention operation configuration 3355. According to certain aspects of the present disclosure, the intervention operation success rate 3340 may be generated by a predictive model, as discussed in more detail herein with respect to FIG. 19.

In an illustrative example of the decision tree, the decision tree may indicate intervention objectives, for example, flow reduction and skin reduction. The decision tree may include a first intervention operation, for example, a wireline generic gauge cutter operation, with an 88% predicted operation success rate, a first duration, and a first cost. The decision tree may include a second intervention operation, for example, a wireline flow scanner operation, with an 80% predicted operation success rate, a second duration, and second cost. The decision tree may include a third intervention operation, for example, a wireline flow-caliper imaging sonde (PFCS-A) operation, with a 87% predicted operation success rate, a third duration, and a third cost. The decision tree may include a fourth intervention operation, for example, a wireline charge operation, with a 90% predicted operation success rate, a fourth duration, and a fourth cost. The decision tree may provide an overall predicted operation success rate of 55.12%, an overall duration, and an overall cost

A well intervention plan report display of the user interface 2110 can be analogous to the well intervention plan report display of FIG. 13.

According to aspects of the present disclosure, machine learning is used to train the predictive model for the intervention operation probability of success. In some aspects, the machine learning algorithm may be used generate the predictive model for intervention operation probability of success prediction. In some aspects, the predictive model is trained to predict the intervention operation probability of success based on a current state, such as based on the inputs from the user 2105. In some aspects, the training involves a reward parameter, which maximizes or minimizes an objective function.

In some aspects, the machine learning algorithm may be modeled as a Markov Decision Process (MDP), may be a reinforcement learning algorithm, a deep learning algorithm, a supervised learning algorithm, an unsupervised learning algorithm, a semi-supervised learning algorithm, a Q-learning algorithm, a value reinforcement algorithm, a polar reinforcement algorithm, a deep convolutional network (DCN), or a combination thereof.

In some examples, the machine learning is performed using a neural network. Neural networks may be designed with a variety of connectivity patterns. In feed-forward networks, information is passed from lower to higher layers, with each neuron in a given layer communicating to neurons in higher layers. A hierarchical representation may be built up in successive layers of a feed-forward network. Neural networks may also have recurrent or feedback (also called top-down) connections. In a recurrent connection, the output from a neuron in a given layer may be communicated to another neuron in the same layer. A recurrent architecture may be helpful in recognizing patterns that span more than one of the input data chunks that are delivered to the neural network in a sequence. A connection from a neuron in a given layer to a neuron in a lower layer is called a feedback (or top-down) connection. A network with many feedback connections may be helpful when the recognition of a high-level concept may aid in discriminating the particular low-level features of an input. Individual nodes in the artificial neural network may emulate biological neurons by taking input data and performing simple operations on the data. The results of the simple operations performed on the input data are selectively passed on to other neurons. Weight values are associated with each vector and node in the network, and these values constrain how input data is related to output data. The weight values may initially be determined by an iterative flow of training data through the network (e.g., weight values are established during a training phase in which the network learns how to identify particular classes by their typical input data characteristics). Different types of artificial neural networks can be used to implement machine learning, such as recurrent neural networks (RNNs), multilayer perceptron (MLP) neural networks, convolutional neural networks (CNNs), and the like. These multi-layered architectures may be trained one layer at a time and may be fine-tuned using back propagation.

In one example, a Random Forest approach machine learning algorithm is used for predicting the intervention operation probability of success. A Random Forest algorithm is a supervised classification ensemble machine learning algorithm. Supervised learning may be useful when large amounts of data are available for model training. With supervised training, the training data contains the input and target values, the algorithm learns a pattern that maps the input values to the output values, and the algorithm uses the pattern to predict future output values based on input values.

The Random Forest algorithm involves creating a number of decision tree during a model training phase. Each decision tree may constructed using a random subset of data from the training data set to measure a random subset of features in each partition. The randomness introduces variability among individual decision trees, reducing the risk of overfitting and improving overall prediction performance. The process known as “bagging” involves training weak models on different subsets of the training data and sampling each subset with replacement. For prediction, the Random Forest algorithm aggregates the results of all the decision trees, either by majority voting (e.g., for classification tasks) or by averaging (e.g., for regression tasks) the prediction of the weak models. This collaborative decision-making process, supported by multiple decision trees with their insights, provides an example stable and precise results.

FIG. 19 depicts an example Random Forest algorithm 3500 for intervention operation probability of success prediction. As shown in FIG. 19, the algorithm may begin with a training data collection phase 3505. In some aspects, the training data collection phase 1505 includes ingestion, parsing, and contextualization of data. In some aspects, the training data collection phase is on-going even after deployment of the predictive model in order to fine tune and improve the model. In some aspects, the training data includes historical information 3510 associated with previous well interventions. In some aspects, the well intervention historical information is collected across many (e.g., all) users of the well intervention planning system 2100, which may be associated with many different wells. In some aspects, the training data include wireline and slickline operational data. The operational logs for the wireline and slickline operations may be collected, processed, and stored as optimized data structures. In some aspects, the training data is stored in a training data repository.

Wireline operations involve the use of a cable (the wireline) to lower tools and instruments into a wellbore for various types of well intervention tasks. The wireline may consist of a core conductor, typically made of steel, surrounded by several layers of armor wires for strength and protection. One type of wireless is electric line (E-line) that contains electrical conductors that transmit real-time data and control signals between the surface and the downhole tools. Another type of wireline is slickline, a simpler, non-conductive wireline without electrical components, used mainly for mechanical operations. Wirelines operations may include logging, such that measurement of physical properties of the formation and the fluids in the wellbore using tools that record various data (e.g., resistivity, porosity, gamma-ray). Wirelines operations may include perforation, the placing and firing of perforation guns to create holes in the casing and cement to allow reservoir fluids to enter the wellbore. Another wireline operation is setting and retrieval, the installation or removal of plugs, chokes, safety valves, packers, and other downhole equipment. Another wireline operation is fishing, the recovery of lost or stuck equipment from the wellbore. Another wireline operation is mechanical services, the performance of tasks such as shifting sleeves, cutting tubulars, cutting paraffin, setting packers, adjusting valves, and other interventions that require mechanical force. Operational data associated with wireless operations may include, but is not limited to depth and pressure, temperature, and fluid type.

According to certain aspects, the training data collection phase 3505 includes a data pre-processing stage 3515. In some aspects, tables may be combined across the available operational data, such as Jobs, Runs, Passes, Wells, Business context. The data may be pre-processed through a variety of techniques such as imputation to handle missing values, removal of outliers, unit standardization, data categorization, class rebalancing, rescaling, and dummy encoding.

In some aspects, data pre-processing stage 3515 may begin with the handling of missing values, such as by imputation or removal of missing values, to ensure a complete and reliable dataset. Next, because Random Forest uses numerical input, categorical variables in the data may be encoded using techniques such as one-hot encoding or label encoding to transform the categorical variables into a numerical format. The data pre-processing stage 3515 may further including scaling and normalization of the data which may help improve the efficiency of the predictive model training process.

According to certain aspects, the training data collection phase 3505 includes a feature generation stage 3520. The feature generation stage 3520 may involve assessing the importance of features within the dataset and the selection of relevant features for the model training. The features may be mapped to labels for the training data. In some aspects, features may selected and input by the user 2105.

The training data collection phase 3505 may further includes addressing imbalanced data, such as by adjusting class weights or employing resampling to ensure balanced representation during training.

As shown in FIG. 19, the algorithm may proceed to a predictive model training phase 3525. The model training phase 3525 may involve using a predictive model to predict well intervention operation probability of success and comparing the predictions to actual outcomes of well intervention operations. Intervention operations may be labeled as successful (e.g., “Objective Achieved”) when the specified intervention operations are achieved for a slickline job or via a user questionnaire for a wireline job. In some aspects, the intervention operations are labeled by the users of the system. A binary classification predictive model may predict a true/false output (e.g., successful or unsuccessful), which may be scored against the label and optimized by comparing different algorithms against the score.

As shown, decision trees 3530 are constructed for the model training. A decision tree is a classification problem, because it may begin with a binary decision. For example, the decision may be the success of an intervention operation. Each node in the decision tree may involve a further binary decision related to the previous binary decision. Observations (data) that fit the criteria of a node may be follow a “Yes” path (e.g., denoted by the checkmarks in the nodes in the decision trees 3530) and observations that do not fit the criteria follow the alternative “No” path (e.g., denoted by the “X” in the nodes in the decision trees 3530). Thus, the nodes in the decision trees 3530 serve to split the data into subsets. The decision trees seeks to find the best splits for the subsets of data, which may be trained through a Classification and Regression Tree (CART) algorithm. Metrics, such as Gini impurity, information gain, or mean square error (MSE), can be used to evaluate the quality of the split. When multiple decision trees form an ensemble in the random forest algorithm, they predict more accurate results.

The Random Forest algorithm may associated with a set of configured hyperparameters which may be specified before the model training and testing phase 3525. For example, the hyperparameters may include the node size, the number of trees, and the number of features sampled.

To ensure that each decision tree 3530 in the ensemble brings a unique perspective, random feature selection may be performed. During the training of each decision tree 3530, a random subset of features may be chosen. This randomness ensures that each tree focuses on different aspects of the data, fostering a diverse set of predictors within the ensemble.

Randomness is injected through feature bagging, adding more diversity to the dataset and reducing the correlation among decision trees. Bagging stage 3535 may be used to test (e.g., verify) the predictive model. The random forest algorithm is made up of a collection of decision trees, and each tree in the ensemble is comprised of a data sample drawn from a training set with replacement. The data sample may be referred to as a bootstrap sample. A portion of the training sample may be set aside as test data, known as the out-of-bag (oob) sample. Bagging is a technique that involves creating multiple bootstrap samples from the original dataset, allowing data instances to be sampled with replacement, resulting in the different subsets of data for each decision tree and introducing variability into the training process making the predictive model more robust.

Depending on the type of problem, the determination of the prediction 3540 will vary. For a regression task, the predictions of the individual decision trees will be averaged, and for a classification task, a majority vote—i.e. the most frequent categorical variable (the mode) across all the decision trees—will yield the predicted class. The voting mechanism ensures a balanced and collective decision-making process. Finally, the oob sample is then used for cross-validation, finalizing that prediction.

Once the predictive model is tested and verified, the model may be deployed in the model deployment phase 3545. The predictive model may then be accessed by the user 2105 for intervention operation probability of success predictions, which may be used to make decision during well intervention planning. For example, as described herein, when the user 2105 builds a well intervention plan using the well intervention planning system 2100, the user 2105 inputs information to the user interface 2110. The input may be fed as features to the predictive model, and the predictive model outputs a probability of success for one or more well intervention operations. The prediction may be displayed to the user 2105. For example, in response to high probability of success, the user 2105 may select the well intervention operation for the well intervention plan. In response to a low probability of success, the user 2105 may specify a contingency well intervention operation, an exit point for the well intervention operation, and/or may select a different well intervention operation for the well intervention plan.

### Example Operations for Predictive Intervention Operation Probability of Success for Well Intervention Planning

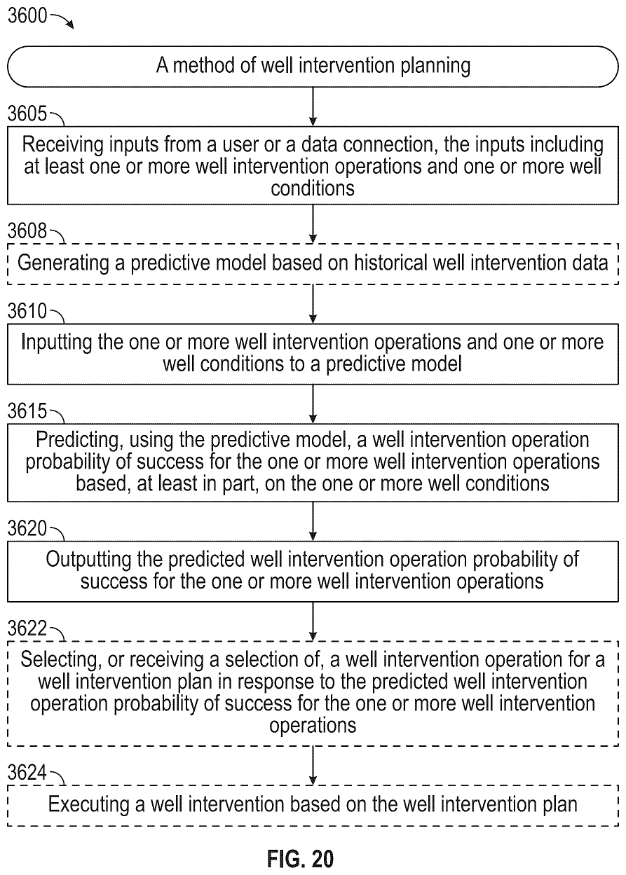

FIG. 20 is a flow diagram depicting an example operations 3600 for predictive intervention operation probability of success for well intervention planning. In some aspects, aspects of the operations 3600 may be performed by a well intervention planning system, which may include local, remote, cloud, virtualized, and/or distributed hardware components.

As shown, the operations 3600 may include, at operation 3605, receiving inputs from a user or a data connection, the inputs including at least one or more well intervention operations and one or more well conditions. In some aspects, the inputs are received at the well intervention planning system from a determination component within the well intervention planning system. In some aspects, the inputs received at the well intervention planning system, via a data connection, from another device or system remote to the well intervention planning system. In some aspects, the inputs are received at the well intervention planning system, via a user interface, from a user of the well intervention planning system.

In some aspects, the one or more conditions input includes at least one of: well completion information, well trajectory information, or well operational information. In some aspects, the well completion information includes at least one of: casing information, tubing information, perforation information, or whether the well is a cased hole or an open hole. In some aspects, the well trajectory information includes at least one of: whether the well is a horizontal well, a vertical well, or a deviated well; an angle at a measured depth; an azimuth at the measured depth; or a true vertical depth at the measured depth. In some aspects, the well operational information includes at least one of: pressure information, temperature information, or fluid density information.

In some aspect, the operations 3600 may include, at operation 3608, generating a predictive model based on historical well intervention data. The operations 3600 may include collecting the historical well intervention data from multiple wells to generate a training dataset. The operations 3600 may include imputing missing values in the historical well intervention data to generate the training dataset. The operations 3600 may include converting non-numerical data in the historical well intervention data to numerical data to generate the training dataset. The operations 3600 may include co scaling data, normalizing data, removing outliers from data, and/or labeling features in the historical well intervention data to generate the training dataset. In some aspects, the predictive model is a machine learning model. Training the machine learning model may include generating a plurality of bootstrap samples from the training dataset; sampling instances of the training dataset with replacement to generate a plurality of random subsets of the training dataset; and generating a plurality of decision trees, wherein the plurality of decision trees are associated with the random subsets of the training dataset.

The operations 3600 may include, at operation 3610, inputting the one or more well intervention operations and one or more well conditions to a predictive model.

The operations 3600 may include, at operation 3615, predicting, using the predictive model, a well intervention operation probability of success for the one or more well intervention operations based, at least in part, on the one or more well conditions. In some aspects, the predictive model is based on historical well intervention data. In some aspects, the historical well intervention data comprises well intervention data collected from multiple wells. In some aspects, the historical well intervention data comprises slickline and wireline operational data associated with previous well intervention operations. In some aspects, the predictive model is a Random Forest machine learning model comprising a plurality of decision trees, each of the plurality of decision trees associated with a random subset of the historical well intervention data. In some aspects, each of the plurality of decision trees comprises a plurality of nodes, each node being associated with a subset of the historical well intervention data corresponding to a feature and a secondary binary prediction associated with the well intervention operation probability of success. In some aspects, predicting the well intervention operation probability of success for the one or more well intervention operations comprises generating well intervention operation probability of success predictions, based on the input, from each the plurality of decision trees; and aggregating the well intervention operation probability of success predictions from the plurality of decision trees. In some aspects, the aggregating includes selecting a well intervention operation probability of success prediction generated by a highest number of the plurality of decision trees. In some aspects, the predictive model is a statistical model. In some aspects, the predictive model is another type of learning model or another type of predictive model.

The operations 3600 may include, at operation 3620, outputting the predicted well intervention operation probability of success for the one or more well intervention operations. In some aspects, outputting the predicted well intervention operation probability of success for the one or more well intervention operations is to a user via a display, such as a local display of the well intervention planning system, a remote display, or a user device. In some aspects, the outputting the predicted well intervention operation probability of success for the one or more well intervention operations is to a well intervention operation selection component of the well intervention planning system.

In some aspects, the operations 3600 may further include, at operation 3622, selecting, or receiving a selection of, a well intervention operation for a well intervention plan in response to the predicted well intervention operation probability of success for the one or more well intervention operations. In some aspects, the well intervention operation is selected automatically by the well intervention planning system. In some aspects, the well intervention operation is selected by a user of the well intervention planning system.

In some aspects, the operations 3600 may further include, at operation 3624, executing a well intervention based on the well intervention plan. In some aspects, executing the well intervention may include performing the well intervention operations according to the well intervention plan. In some aspects, the well intervention plan is executed automatically by the well intervention planning system. In some aspects, the well intervention is executed by a user of the well intervention planning system.

### Example System for Predictive Intervention Operation Probability of Success for Well Intervention Planning

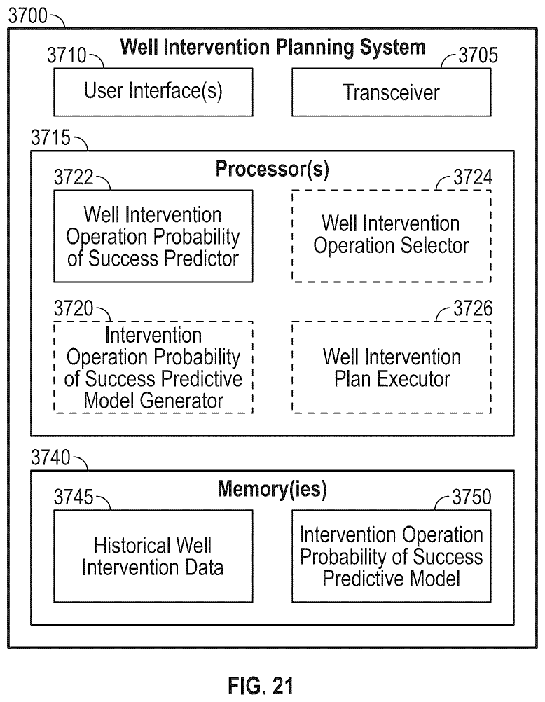

According to certain aspects, a well intervention planning system 3700 with predictive intervention operation probability of success is provided, as shown in FIG. 21. The well intervention planning system 3700 may run on a single computing device or across multiple devices.

As shown, the well intervention planning system 3700 may include one or more user interfaces 3710 on the one or more devices comprising the well intervention planning system 3700 that allow a user to interact with the well intervention planning system 3700. The one or more user interfaces 3710 may be an example of the user interface 2110 of FIG. 17. In some examples, the user interface(s) 3710 may include a graphical user interface (GUI) that display to a user and/or accepts touch screen inputs from the user. The user interface(s) 3710 may include one or more input/output (IOs) interfaces that allows one or more I/O devices (e.g., keyboards, displays, mouse devices, pen inputs, microphones, etc.) to connect to the well intervention planning system 3700. In some aspects, the user interface(s) 3710 are configured to receive user input, including intervention objectives, well conditions, user preferences, and/or well intervention operations and technologies, as described herein. In some aspects, the user interface(s) 3710 are configured to receive, from the user, a selection of a well intervention operation for a well intervention plan in response to the predicted well intervention operation probability of success for the one or more well intervention operations;

As shown in FIG. 21, the well intervention planning system 3700 may include a transceiver 3705 and one or more network interface(s). The transceiver 3705 and network interface(s) may allow the well intervention planning system 3700 to connect to a network (e.g., such as the Internet, a local area network (LAN), a wireless LAN (WLAN), a wireless wide area network (WWAN), Wi-Fi, etc.) and/or to communicate with other devices, such as to communicatively connect devices within the well intervention planning system 3700 and/or devices external to the well intervention planning system 3700. In some aspects, the transceiver 3605 and one or more network interface(s) may be configured to receive input, via a data connection, including intervention objectives, well conditions, user preferences, and/or well intervention operations and technologies, as described herein. In some aspects, the transceiver 3605 and one or more network interface(s) may be configured to collect historical well intervention plan information and statistics from multiple users of the well intervention planning system 3700. In some aspects, the transceiver 3605 and one or more network interface(s) may be configured to receive, via a data connection, a selection of a well intervention operation for a well intervention plan in response to the predicted well intervention operation probability of success for the one or more well intervention operations.

As shown, the well intervention planning system may include a processing system including one or more processor(s) 3715. The one or more processor(s) 3715 may be local to the well intervention planning system 3700 or remote (e.g., cloud computing resources). The one or more processor(s) 3715 may comprise one or more central processing units (CPUs). The CPU may have multiple processing cores. In some aspects, the processor(s) 3715 may include an intervention operation probability of success predictive model generator 3720 configured to generate the intervention operation probability of success predictive model 3750 based on the historical well intervention data 3745. In some aspects, the processor(s) 3715 may include a well intervention operation probability of success predictor processor 3722 configured to provide the inputs to the intervention operation probability of success predictive model 3750 and receive an output of a predicted well intervention operation probability of success from the intervention operation probability of success predictive model 3750, and output the predicted well intervention operation probability of success. In some aspects, the processor(s) 3715 may include a well intervention operation selector 3724 configured to select a well intervention operation for a well intervention plan in response to the predicted well intervention operation probability of success for the one or more well intervention operations. In some aspects, the processor(s) 3715 may include a well intervention plan executor 3726 configured to execute a well intervention based on the well intervention plan.

The processing system may further include memory(ies) 3740 and/or storage(s), which may be local to the well intervention planning system 3700 or remote (e.g., cloud storage). The memory 3740 may represent a random access memory (RAM). The storage may be a disk drive, a combination of fixed or removable storage devices, such as fixed disc drives, removable memory cards or optical storage, network attached storage (NAS), or a storage area-network (SAN). The CPU may retrieve and execute programming instructions stored in the memory(ies) 3740. Similarly, the CPU may retrieve and store application data residing in the memory(ies) 3740. As shown in FIG. 21, the memory(ies) 1740 may store historical well intervention plan information 3745. As shown in FIG. 21, the memory(ies) 3740 may store the predictive model 3750 for the intervention operation probability of success.

In some aspects, computing resources, including processing and/or memory resources, may be virtualized. Virtual machines (VMs) are software-based emulations of physical computers that run on host hardware and may provide a virtualized computing environment including operating systems, CPU allocation, memory, storage, and network interfaces. In some aspects, the well intervention planning system 3700 includes one or more VMs configured to perform predictive intervention operation chance of success prediction for well intervention planning, the VMs using computing resources of the well intervention planning system 3700, such as processor(s) 3715 and/or memory(ies) 3740.

### Example Clauses

Implementation examples are described in the following numbered aspects:

Aspect 1: An automated well intervention planning system, the system comprising: one or more memories storing computer executable code; an interface configured to receive inputs, the inputs including at least one or more well intervention objectives and one or more well conditions; and one or more processors configured to execute the computer executable code to generate a well intervention plan based on the inputs.

Aspect 2: The system of Aspect 1, further comprising a display, wherein the one or more processors are further configured to output a recommendation, to a user, of the generated well intervention plan via the display.

Aspect 3: The system of any combination of Aspects 1-2, wherein the one or more processors are further configured to execute the generated well intervention plan to perform one or more well interventions on one or more selected wells.

Aspect 4: The system of any combination of Aspects 1-3, wherein the inputs further include a selection of one or more wells for generating one or more well intervention plans.

Aspect 5: The system of any combination of Aspects 1-4, wherein the one or more well intervention objectives inputs include at least one of: one or more target markets, one or more well environments, one or more well symptoms, or one or more well invention types.

Aspect 6: The system of any combination of Aspects 1-5, wherein the one or more well conditions inputs includes at least one of: well completion information, well trajectory information, or well operational information.

Aspect 7: The system of any combination of Aspects 1-6, wherein: the well completion information includes at least one of: casing information, tubing information, perforation information, or whether the well is a cased hole or an open hole; the well trajectory information includes at least one of: whether the well is a horizontal well, a vertical well, or a deviated well; an angle at a measured depth; an azimuth at the measured depth; or a true vertical depth at the measured depth; and the well operational information includes at least one of: pressure information, temperature information, or fluid density information.

Aspect 8: The system of any combination of Aspects 1-7, wherein the one or more processors are configured to generate the well intervention plan by: automatically selecting one or more well intervention technologies associated with one or more well intervention operations; and automatically specifying a sequence of the one or more well intervention technologies associated with the one or more well intervention operations.

Aspect 9: The system of any combination of Aspects 1-8, wherein the one or more processors are configured to: search a database for one or more well intervention plans associated with the one or more well intervention objectives and the one or more well conditions; identify a well intervention plan, among the one or more well intervention plans in the database, associated with a highest amount of well intervention objectives and well conditions that match the one or more well intervention objectives and the one or more well conditions; and generate the well intervention plan based on the identified well intervention plan.

Aspect 10: The system of Aspect 9, wherein: multiple well intervention plans in the database having an equal amount of matching well intervention objectives and well conditions are identified; and the one or more processors are further configured to select the well intervention plan of the multiple well intervention plans that satisfies a criteria.

Aspect 11: The system of Aspect 10, wherein the criteria comprises at least one of: the well intervention plan associated with a highest count among the multiple well intervention plans, the well intervention plan associated with a shortest duration among the multiple well intervention plans, the well intervention plan associated with a lowest cost among the multiple well intervention plans, or one or more user specified preferences.

Aspect 12: The system of any combination of Aspects 9-11, wherein the one or more processors are further configured to: search the database for one or more contingency well intervention plans based on the generated well intervention plan; and generate a contingency well intervention plan based on the one or more contingency well intervention plans.

Aspect 13: The system of Aspect 12, wherein the one or more processors are configured to identify at least one contingency well intervention technology, associated with a well intervention operation, that is associated with at least one well intervention technology of the generated well intervention plan.

Aspect 14: The system of Aspect 13, wherein: multiple contingency well intervention technologies associated with the well intervention technology of the generated well intervention plan are identified; and the one or more processors are further configured to select a contingency well intervention technology of the multiple contingency well intervention technologies that satisfies a criteria.

Aspect 15: The system of any combination of Aspects 9-14, wherein the one or more processors are configured to: use a physics-based model of the well to select a subset of the one or more well intervention plans in the database; and identify the well intervention plan from among the subset of the one or more well intervention plans.

Aspect 16: The system of any combination of Aspects 1-15, wherein: the inputs further include well equipment information comprising at least one of: equipment procurement information, equipment inventory information, or equipment maintenance information; and the one or more processors are configured to generate the well intervention plan further based on the equipment information.

Aspect 17: The system of any combination of Aspects 1-16, wherein the interface comprises a user interface configured to receive one or more of the inputs from the user.

Aspect 18: A method for performing the automated well intervention planning of any combination of Aspects 1-17.

Aspect 19: An apparatus for performing the automated well intervention planning of any combination of Aspects 1-17.

Aspect 20: A non-transitory computer readable medium for performing the automated well intervention planning of any combination of Aspects 1-17.

Aspect 21: A method for well intervention planning, the method comprising: receiving inputs from a user or a data connection, the inputs including at least one or more well intervention operations and one or more well conditions; inputting the one or more well intervention operations and one or more well conditions to a predictive model; predicting, using the predictive model, a well intervention operation probability of success for the one or more well intervention operations based, at least in part, on the one or more well conditions; and outputting the predicted well intervention operation probability of success for the one or more well intervention operations.

Aspect 22: The method of aspect 21, wherein the one or more conditions input includes at least one of: well completion information, well trajectory information, or well operational information.

Aspect 24. The method of aspect 22, wherein: the well completion information includes at least one of: casing information, tubing information, perforation information, or whether the well is a cased hole or an open hole; the well trajectory information includes at least one of: whether the well is a horizontal well, a vertical well, or a deviated well; an angle at a measured depth; an azimuth at the measured depth; or a true vertical depth at the measured depth; and the well operational information includes at least one of: pressure information, temperature information, or fluid density information.

Aspect 25: The method of any combination of aspects 21-24, wherein the predictive model is a statistical model.

Aspect 26: The method of any combination of aspects 21-24, wherein the predictive model is a machine learning model.

Aspect 27: The method of any combination of aspects 21-26, further comprising generating the predictive model based on historical well intervention data.

Aspect 28: The method of aspect 27, wherein the historical well intervention data comprises slickline and wireline operational data associated with previous well intervention operations.

Aspect 29: The method of aspect 28, further comprising collecting the historical well intervention data from multiple wells to generate a training dataset.

Aspect 30: The method of aspect 29, wherein generating the training dataset comprises imputing missing values in the historical well intervention data.

Aspect 31: The method of any combination of aspects 28-30, wherein generating the training data set comprises converting non-numerical data in the historical well intervention data to numerical data.

Aspect 32: The method of any combination of aspects 28-31, wherein generating the training dataset comprises at least one of: scaling data, normalizing data, removing outliers from data, or labeling features in the historical well intervention data.

Aspect 33: The method of any combination of aspects 28-32, wherein the predictive model is a machine learning model, and wherein training the machine learning model comprises: generating a plurality of bootstrap samples from the training dataset; sampling instances of the training dataset with replacement to generate a plurality of random subsets of the training dataset; and generating a plurality of decision trees, wherein the plurality of decision trees are associated with the random subsets of the training dataset.

Aspect 34: The method of any combination of aspects 21-33, wherein the user interface or data connection is further configured to receive a selection of a well intervention operation for a well intervention plan in response to the predicted well intervention operation probability of success for the one or more well intervention operations.

Aspect 35: The method of any combination of aspects 21-33, wherein the one or more processors are further configured to select the well intervention operation for the well intervention plan in response to the predicted well intervention operation probability of success for the one or more well intervention operations.

Aspect 36: The method of any combination of aspects 21-35, wherein the predictive model is a Random Forest machine learning model comprising a plurality of decision trees, and wherein each of the plurality of decision trees is associated with a random subset of the historical well intervention data.

Aspect 37: The method of aspect 36, wherein each of the plurality of decision trees comprises a plurality of nodes, and wherein each node is associated with a subset of the historical well intervention data corresponding to a feature and a secondary binary prediction associated with the well intervention operation probability of success.

Aspect 38: The method of aspect 37, wherein the predicting the well intervention operation probability of success for the one or more well intervention operations comprises: generating well intervention operation probability of success predictions, based on the input, from each the plurality of decision trees; and aggregating the well intervention operation probability of success predictions from the plurality of decision trees, wherein the aggregating includes selecting a well intervention operation probability of success prediction generated by a highest number of the plurality of decision trees.

Aspect 39: A system for performing the predictive intervention operation probability of success for well intervention planning of any combination of aspects 21-38.

Aspect 40: The system of aspect 39, wherein one or more components of the system are located in a cloud.

Aspect 41: The system of aspect 39, wherein one or more components of the system comprise virtual machines.

Aspect 42: An apparatus for performing the predictive intervention operation probability of success for well intervention planning of any combination of aspects 21-38.

Aspect 43: The apparatus of aspect 42, wherein one or more components of the apparatus are located in a cloud.

Aspect 44: The apparatus of aspect 42, wherein one or more components of the apparatus comprise virtual machines.

Aspect 45: A non-transitory computer readable medium for performing the predictive intervention operation probability of success for well intervention planning of any combination of aspects 21-38.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more. ” Unless specifically stated otherwise, the term “some” refers to one or more. No claim element is to be construed under the provisions of 35 U.S.C. § 112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. An automated well intervention planning system, the system comprising:
one or more memories storing computer executable code;
an interface configured to receive inputs, the inputs including at least one or more well intervention objectives and one or more well conditions; and
one or more processors configured to execute the computer executable code to generate a well intervention plan based on the inputs.

2. The system of claim 1, further comprising a display, wherein the one or more processors are further configured to output a recommendation, to a user, of the generated well intervention plan via the display.

3. The system of claim 1, wherein the one or more processors are further configured to execute the generated well intervention plan to perform one or more well interventions on one or more selected wells.

4. The system of claim 1, wherein the inputs further include a selection of one or more wells for generating one or more well intervention plans.

5. The system of claim 1, wherein the one or more well intervention objectives inputs include at least one of: one or more target markets, one or more well environments, one or more well symptoms, or one or more well invention types.

6. The system of claim 1, wherein the one or more well conditions inputs includes at least one of: well completion information, well trajectory information, or well operational information.

7. The system of claim 1, wherein:
the well completion information includes at least one of: casing information, tubing information, perforation information, or whether the well is a cased hole or an open hole;
the well trajectory information includes at least one of: whether the well is a horizontal well, a vertical well, or a deviated well; an angle at a measured depth; an azimuth at the measured depth; or a true vertical depth at the measured depth; and
the well operational information includes at least one of: pressure information, temperature information, or fluid density information.

8. The system of claim 1, wherein the one or more processors are configured to generate the well intervention plan by:
automatically selecting one or more well intervention technologies associated with one or more well intervention operations; and
automatically specifying a sequence of the one or more well intervention technologies associated with the one or more well intervention operations.

9. The system of claim 1, wherein the one or more processors are configured to:
search a database for one or more well intervention plans associated with the one or more well intervention objectives and the one or more well conditions;
identify a well intervention plan, among the one or more well intervention plans in the database, associated with a highest amount of well intervention objectives and well conditions that match the one or more well intervention objectives and the one or more well conditions; and
generate the well intervention plan based on the identified well intervention plan.

10. The system of claim 9, wherein:
multiple well intervention plans in the database having an equal amount of matching well intervention objectives and well conditions are identified; and
the one or more processors are further configured to select the well intervention plan of the multiple well intervention plans that satisfies a criteria.

11. The system of claim 10, wherein the criteria comprises at least one of: the well intervention plan associated with a highest count among the multiple well intervention plans, the well intervention plan associated with a shortest duration among the multiple well intervention plans, the well intervention plan associated with a lowest cost among the multiple well intervention plans, or one or more user specified preferences.

12. The system of claim 9, wherein the one or more processors are further configured to:
search the database for one or more contingency well intervention plans based on the generated well intervention plan; and
generate a contingency well intervention plan based on the one or more contingency well intervention plans.

13. The system of claim 12, wherein the one or more processors are configured to identify at least one contingency well intervention technology, associated with a well intervention operation, that is associated with at least one well intervention technology of the generated well intervention plan.

14. The system of claim 13, wherein:
multiple contingency well intervention technologies associated with the well intervention technology of the generated well intervention plan are identified; and
the one or more processors are further configured to select a contingency well intervention technology of the multiple contingency well intervention technologies that satisfies a criteria.

15. The system of claim 9, wherein the one or more processors are configured to:
use a physics-based model of the well to select a subset of the one or more well intervention plans in the database; and
identify the well intervention plan from among the subset of the one or more well intervention plans.

16. The system of claim 1, wherein:
the inputs further include well equipment information comprising at least one of: equipment procurement information, equipment inventory information, or equipment maintenance information; and
the one or more processors are configured to generate the well intervention plan further based on the equipment information.

17. The system of claim 1, wherein the interface comprises a user interface configured to receive one or more of the inputs from the user.

18. The system of claim 1, wherein the one or more processors are further configured to:
input the one or more well intervention operations and one or more well conditions to a predictive model;
predict, using the predictive model, a well intervention operation probability of success for the one or more well intervention operations based, at least in part, on the one or more well conditions; and
output the predicted well intervention operation probability of success for the one or more well intervention operations.

19. A method for automated well intervention planning, the method comprising:
receiving inputs, the inputs including at least one or more well intervention objectives and one or more well conditions; and
generating a well intervention plan based on the inputs.

20. A computer readable medium storing computer executable code for automated well intervention planning, the computer executable code comprising:
code for receiving inputs, the inputs including at least one or more well intervention objectives and one or more well conditions; and
code for generating a well intervention plan based on the inputs.
